(19) United States
(12) Patent Application Publication
(10) Pub. No.: US 2024/0301115 A1
(43) Pub. Date: Sep. 12, 2024

(54) NEGATIVE-TYPE PHOTOSENSITIVE POLYMER, POLYMER SOLUTION, NEGATIVE-TYPE PHOTOSENSITIVE RESIN COMPOSITION, CURED FILM, AND SEMICONDUCTOR DEVICE

(71) Applicant: SUMITOMO BAKELITE CO., LTD., Tokyo (JP)

(72) Inventors: Keita IMAI, Tokyo (JP); Akihiko OTOGURO, Tokyo (JP); Kazuya NAKASHIMA, Tokyo (JP)

(73) Assignee: SUMITOMO BAKELITE CO., LTD., Tokyo (JP)

(21) Appl. No.: 18/570,237

(22) PCT Filed: Jun. 22, 2022
(86) PCT No.: PCT/JP2022/024912

§ 371 Date: Dec. 14, 2023

(30) Foreign Application Priority Data
Jun. 25, 2021 (JP) 2021-105682
Feb. 10, 2022 (JP) 2022-019323

(51) Int. Cl. C08F 290/14; C08F 222/32; C08G 73/10; C08G 73/12; G03F 7/038

(52) U.S. Cl. CPC C08F 290/145; C08F 222/32; C08G 73/1067; C08G 73/12; G03F 7/0387

(57) ABSTRACT

A negative-type photosensitive polymer of the present invention is a solvent-soluble negative-type photosensitive polymer which has a structural unit containing an imide ring, the negative-type photosensitive polymer containing a group having a terminal double bond, in which an average value of positive electric charges (δ+) of two carbonyl carbons of the imide ring is equal to or less than 0.099 as calculated by a charge equilibration method.

### TECHNICAL FIELD

The present invention relates to a negative-type photosensitive polymer, a polymer solution, a negative-type photosensitive resin composition, a cured film, and a semiconductor device.

### BACKGROUND ART

Polyimide resins have a high level of mechanical strength, heat resistance, insulation, and solvent resistance, and thus have been widely used as a thin film for a protective material, an insulating material, an electronic material such as a color filter, and the like in liquid crystal display devices and semiconductors.

Patent Document 1 discloses a resin composition containing a polyimide resin having a specific organic group. The document discloses that according to the resin composition, the resin composition is easily dissolved in an alkali developing solution before exposure, and is insoluble in the alkali developing solution after exposure, thereby making the shrinkage of a film when curing low, which makes it possible to obtain a high rectangular pattern after curing.

### RELATED DOCUMENT

### Patent Document

[Patent Document 1] Japanese Laid-Open Patent Publication No. 2018-070829

### SUMMARY OF THE INVENTION

### Technical Problem

However, it was found that mechanical strength such as elongation is reduced by hydrolysis in the conventional polymer disclosed in Patent Document 1. In addition, a negative-type photosensitive polymer is also required to have excellent solubility in general solvents used in varnishes.

### Solution to Problem

The inventors of the present invention have found that, in a negative-type photosensitive polymer having a predetermined structural unit containing an imide ring, hydrolysis is inhibited when positive electric charges of carbonyl carbons of the imide ring are within a predetermined range, and thereby the present invention was completed.

In other words, the present invention can be described below.

[1] A solvent-soluble negative-type photosensitive polymer which has a structural unit containing an imide ring, the negative-type photosensitive polymer containing a group having a terminal double bond,
in which an average value of positive electric charges (δ+) of two carbonyl carbons of the imide ring is equal to or less than 0.099 as calculated by a charge equilibration method.

[2] The negative-type photosensitive polymer according to [1], in which a fluorine atom is not contained in a molecular structure.

[3] The negative-type photosensitive polymer according to [1] or [2], in which the structural unit is represented by General Formula (1).

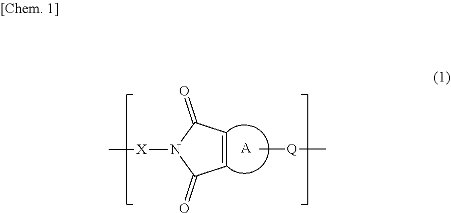

(In General Formula (1), X represents a divalent organic group including an aromatic group; A represents a ring structure having two carbons of the imide ring; and Q represents a divalent organic group.)

[4] The negative-type photosensitive polymer according to [3], further containing an electron-donating group at two ortho positions with respect to a carbon atom bonded to a nitrogen atom in General Formula (1), in which the aromatic group included in the divalent organic group as X in General Formula (1) is bonded to the nitrogen atom.

[5] The negative-type photosensitive polymer according to [3] or [4], in which X in General Formula (1) is a divalent group represented by General Formula (1a) or General Formula (1b).

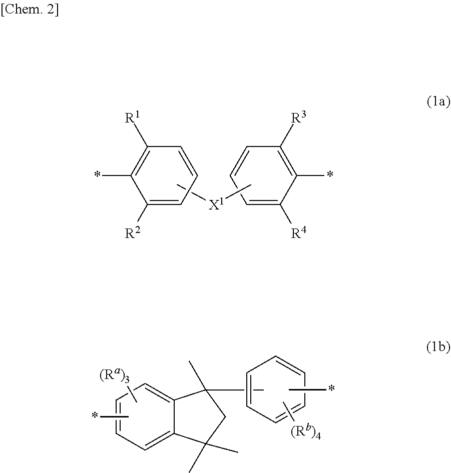

(In General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups; X¹ represents a single bond, —SO₂—, —C(═O)—, a linear or branched alkylene group having 1 to 5 carbon atoms, or a fluorenylene group; and * represents a bonding site, and
in General Formula (1b), R^{a} and R^{b} each independently represent a hydrogen atom, an alkyl group having 1 to 3 carbon atoms, or an alkoxy group having 1 to 3 carbon atoms, provided that a plurality of R^{a}'s may be the same as or different from each other, and a plurality of R^{b}'s may be the same as or different from each other; and * represents a bonding site.)

[6] The negative-type photosensitive polymer according to any one of [3] to [5], in which X in General Formula (1) includes a divalent group represented by General Formula (1c) having a group having a terminal double bond.

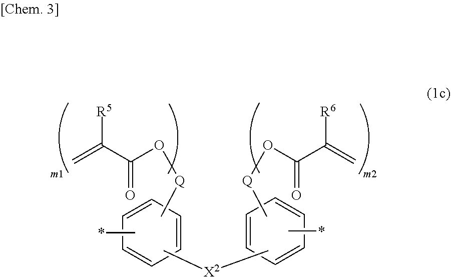

(In General Formula (1c), Q's each represent divalent to tetravalent organic groups having 1 to 10 carbon atoms, provided that a plurality of Q's may be the same as or different from each other; R⁵ and R⁶ each independently represent a hydrogen atom, an alkyl group having 1 to 3 carbon atoms, or an alkoxy group having 1 to 3 carbon atoms; m1 and m2 each independently represent an integer of 1 to 3; X² represents a single bond, —SO₂—, —C(═O)—, or a linear or branched alkylene group having 1 to 5 carbon atoms; and * represents a bonding site.)

[7] The negative-type photosensitive polymer according to any one of [1] to [5], in which the negative-type photosensitive polymer contains the group having a terminal double bond at at least one of both terminals.

[8] The negative-type photosensitive polymer according to any one of [3] to [7], in which A in General Formula (1) is an aromatic ring.

[9] The negative-type photosensitive polymer according to any one of [3] to [8], in which Q in General Formula (1) is a divalent group containing an imide ring.

[10] The negative-type photosensitive polymer according to any one of [5] to [9], in which the structural unit represented by General Formula (1) includes a structural unit represented by General Formula (1-1).

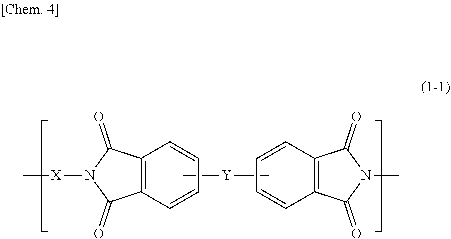

(In General Formula (1-1), X is the divalent group represented by General Formula (1a) or General Formula (1b); and Y is a divalent organic group.)

[11] The negative-type photosensitive polymer according to [10], in which X in General Formula (1-1) includes a divalent group represented by General Formula (1c).

[12] The negative-type photosensitive polymer according to or [11], in which Y in General Formula (1-1) is a divalent organic group selected from General Formula (a1-1), General Formula (a1-2), General Formula (a1-3), and General Formula (a1-4).

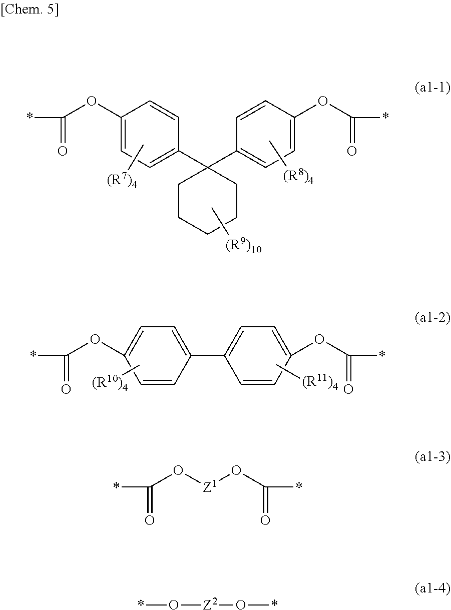

(In General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other; R⁹ represents a hydrogen atom, an alkyl group having 1 to 3 carbon atoms, or an alkoxy group having 1 to 3 carbon atoms, provided that a plurality of R⁹'s may be the same as or different from each other; and * represents a bonding site,
in General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other; and * represents a bonding site,
in General Formula (a1-3), Z¹ represents an alkylene group having 1 to 5 carbon atoms or a divalent aromatic group; and * represents a bonding site, and
in General Formula (a1-4), Z² represents a divalent aromatic group; and * represents a bonding site.)

[13] The negative-type photosensitive polymer according to any one of [1] to [12], in which equal to or more than 5% by mass of the negative-type photosensitive polymer is dissolved in a solvent selected from N-methyl-2-pyrrolidone, N-ethyl-2-pyrrolidone, γ-butyrolactone (GBL), and cyclopentanone.

[14] The negative-type photosensitive polymer according to any one of [1] to [13], in which equal to or more than 5% by mass of the negative-type photosensitive polymer is dissolved in γ-butyrolactone (GBL).

[15] The negative-type photosensitive polymer according to any one of [1] to [14], in which a reduction rate of a weight-average molecular weight measured under the following condition is equal to or less than 15%.

### (Condition)

When 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression.

Expression: [(weight-average molecular weight before test−weight-average molecular weight after test)/weight-average molecular weight before test]×100

[16] A polymer solution containing the negative-type photosensitive polymer according to any one of [1] to.

[17] A negative-type photosensitive resin composition containing:
(A) the negative-type photosensitive polymer according to any one of [1] to;
(B) a crosslinking agent including a polyfunctional (meth)acrylate; and
(C) a photopolymerization initiator.

[18] A cured film containing a cured product of the negative-type photosensitive resin composition according to [17].

[19] A semiconductor device containing a resin film including a cured product of the negative-type photosensitive resin composition according to.

In the present invention, the term “positive electric charge (δ+)” means that the electric charges on atoms in a molecule are calculated by a charge equilibration method (Charge (Q) Equilibration (Eq): QEq) to denote a positive electric charge on a predetermined atom with delta plus (δ+).

The above-mentioned charge equilibration method is as follows.

When atoms form a bond, the electron density is changed until the electronegativities are equal to each other (until a balance is achieved). First, electric charges on all atoms in a molecule start from 0, and electrons flow from atoms with a low electronegativity to atoms with a high electronegativity. When electrons are stored on the atom, the electronegativity is reduced, and when a balance is achieved, the electronegativities of each atom become equal to each other, and the flow of electrons is stopped. In the charge equilibration method, the above-described repeating calculation is carried out to calculate the electric charges on the atom in the molecule to denote the positive electric charge of a predetermined atom with delta plus (δ+) and denote the negative electric charge of a predetermined atom with delta minus (δ−).

In addition, the negative-type photosensitive polymer of the present invention is dissolved in a solvent and used as a varnish. The term “solvent-soluble” means soluble in any of general solvents used in varnishes. Examples of the general solvents include N-methyl-2-pyrrolidone, N-ethyl-2-pyrrolidone, γ-butyrolactone (GBL), and cyclopentanone.

The term “soluble” means that equal to or more than 5% by mass of the negative-type photosensitive polymer of the present invention is dissolved in 100% by mass of these predetermined solvents.

### Advantageous Effects of Invention

According to the present invention, it is possible to provide a negative-type photosensitive polymer, from which a cured product such as a film is obtained, and a negative-type photosensitive resin composition containing the polymer, provided that in the cured product such as a film, the solubility in organic solvents is excellent, and also, hydrolysis is inhibited, thereby minimizing a reduction in mechanical strength such as elongation.

### BRIEF DESCRIPTION OF THE DRAWINGS

FIG. 1 is a schematic cross-sectional view of a semiconductor device of the present embodiment.

### DESCRIPTION OF EMBODIMENTS

Hereinafter, embodiments of the present invention will be described with reference to drawings. In all the drawings, the same components are designated by the same reference numerals, and description thereof will not be repeated as appropriate. In addition, for example, “1 to 10” represents from “equal to or more than 1” and “equal to or less than 10” unless otherwise specified.

A solvent-soluble negative-type photosensitive polymer of the present embodiment is a polymer which has a structural unit containing an imide ring and contains a group having a terminal double bond.

An average value of positive electric charges (δ+) of two carbonyl carbons of the above-mentioned imide ring is equal to or less than 0.099, preferably equal to or less than 0.098, more preferably equal to or less than 0.097, and further preferably equal to or less than 0.095 as calculated by a charge equilibration method.

Thus, it is possible to provide a cured product such as a film in which the solubility in organic solvents is excellent, and also, hydrolysis is inhibited, thereby minimizing a reduction in mechanical strength such as elongation.

In addition, the lower limit value of the average value of the positive electric charges (δ+) of two carbonyl carbons of the above-mentioned imide ring is not particularly limited, but is preferably equal to or more than 0.070, more preferably equal to or more than 0.080, and further preferably equal to or more than 0.085. When the average value is equal to or more than the lower limit value, it is thought that the coloration caused by an electric charge bias can be prevented, and it is thought that a decrease in sensitivity when the negative-type photosensitive polymer of the present embodiment is formed into a photosensitive resin composition can be minimized.

The upper limit value and the lower limit value can be arbitrarily combined.

According to the negative-type photosensitive polymer of the present embodiment, it is possible to provide a cured product such as a film in which the solubility in organic solvents is excellent, and also, hydrolysis is inhibited, thereby minimizing a reduction in mechanical strength such as elongation.

The solvent-soluble negative-type photosensitive polymer of the present embodiment may contain a fluorine atom in the molecular structure within a range not affecting the effects of the present invention as long as the above-mentioned average value of the positive electric charges (δ+) of carbonyl carbons is within a predetermined range, but it is preferable that a fluorine atom having a strong electron-withdrawing character be not contained in the molecular structure.

The structural unit containing the imide ring and included the solvent-soluble negative-type photosensitive polymer can be represented by General Formula (1) below.

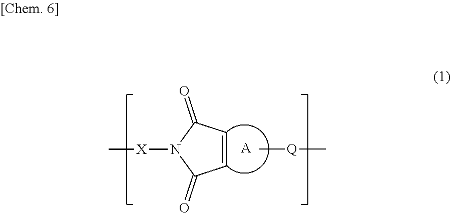

A in General Formula (1) represents a ring structure having two carbons of an imide ring, and is preferably an aromatic ring such as a benzene ring or a naphthalene ring.

Q in General Formula (1) represents a divalent organic group, and is preferably a divalent group containing an imide ring.

In General Formula (1), X represents a divalent organic group including an aromatic group.

The aromatic group included in the divalent organic group as X in General Formula (1) above is preferably bonded to a nitrogen atom in General Formula (1) above. The two ortho positions with respect to the carbon atom of the aromatic group bonded to the above-mentioned nitrogen atom more preferably have an electron-donating group, and further preferably have an asymmetrical electron-donating group. Examples of the electron-donating groups include a hydrogen atom, an alkyl group having 1 to 3 carbon atoms, and an alkoxy group having 1 to 3 carbon atoms.

Examples of the above-mentioned divalent organic groups as X include a divalent group represented by General Formula (1a) below or General Formula (1b) below.

X can include at least one divalent group represented by General Formula (1a) or at least one divalent group represented by General Formula (1b), and can also include a combination of these groups.

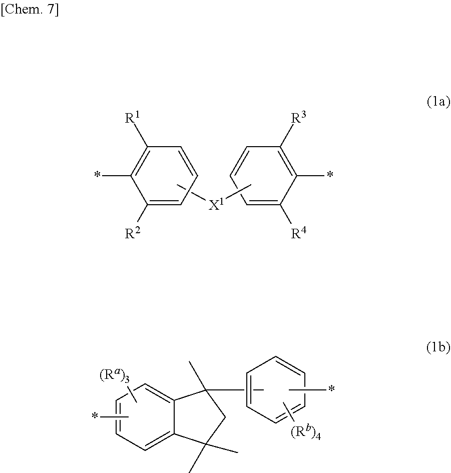

In General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups.

X¹ represents a single bond, —SO₂—, —C(═O)—, a linear or branched alkylene group having 1 to 5 carbon atoms, or a fluorenylene group. * represents a bonding site.

In General Formula (1b), R^{a} and R^{b} each independently represent a hydrogen atom, an alkyl group having 1 to 3 carbon atoms, or an alkoxy group having 1 to 3 carbon atoms. Provided that a plurality of R^{a}'s may be the same as or different from each other, and a plurality of R^{b}'s may be the same as or different from each other. * represents a bonding site.

The condition under which two ortho positions (R¹ and R² (or R³ and R⁴)) with respect to the carbon atom of a benzene ring directly bonded to the nitrogen atom of General Formula (1) have a predetermined electron-donating group is preferable from the viewpoint of the effects of the present invention. X in General Formula (1) above is more preferably the divalent group represented by General Formula (1a) above.

When the side chain has the group having a terminal double bond, X can include a divalent group represented by General Formula (1c) below.

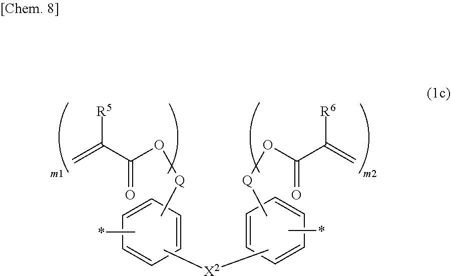

In General Formula (1c), Q represents divalent to tetravalent organic groups having 1 to 10 carbon atoms, provided that a plurality of Q's may be the same as or different from each other.

Examples of the divalent to tetravalent organic groups having 1 to 10 carbon atoms include an ester group, divalent to tetravalent aliphatic hydrocarbon groups having 1 to 10 carbon atoms, and divalent to tetravalent alicyclic hydrocarbon groups having 3 to 10 carbon atoms. These hydrocarbon groups may contain heteroatoms such as oxygen, nitrogen, and sulfur atoms, and may have an ester bond, a thioester bond, a urethane bond, a thiourethane bond, a urea bond, or the like in their structure.

R⁵ and R⁶ each independently represent a hydrogen atom, an alkyl group having 1 to 3 carbon atoms, or an alkoxy group having 1 to 3 carbon atoms.

m1 and m2 each independently represent an integer of 1 to 3.

X² represents a single bond, —SO₂—, —C(═O)—, or a linear or branched alkylene group having 1 to 5 carbon atoms. * represents a bonding site.

Specifically, the structural unit represented by General Formula (1) above preferably includes a structural unit represented by General Formula (1-1) below.

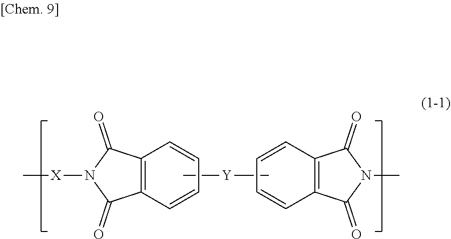

Examples of X in General Formula (1-1) include a divalent group represented by General Formula (1a) above or General Formula (1b) above.

At least one of both terminals, preferably both terminals, of the solvent-soluble negative-type photosensitive polymer can have the group having a terminal double bond at the side chain.

When the side chain has the group having a terminal double bond, X can include the divalent group represented by General Formula (1c) below.

Y in General Formula (1-1) is a divalent organic group.

The divalent organic group as Y can be selected from General Formula (a1-1) below, General Formula (a1-2) below, General Formula (a1-3) below, and General Formula (a1-4) below.

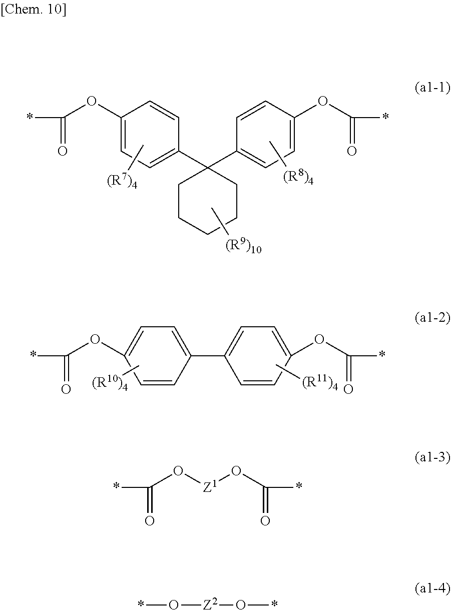

In General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other.

From the viewpoint of the effects of the present invention, R⁷ and R⁸ are preferably a hydrogen atom or an alkyl group having 1 to 3 carbon atoms, and more preferably a hydrogen atom.

R⁹ represents a hydrogen atom, an alkyl group having 1 to 3 carbon atoms, or an alkoxy group having 1 to 3 carbon atoms, provided that a plurality of R⁹'s may be the same as or different from each other.

From the viewpoint of the effects of the present invention, R⁹ is preferably a hydrogen atom or an alkyl group having 1 to 3 carbon atoms, and more preferably a hydrogen atom.

* represents a bonding site.

In General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other.

From the viewpoint of the effects of the present invention, it is preferable that R¹⁰ and R¹¹ be a hydrogen atom or an alkyl group having 1 to 3 carbon atoms; it is more preferable that at least one of R¹⁰'s and at least one of R¹¹'s be an alkyl group having 1 to 3 carbon atoms; it is further preferable that three R¹⁰'s be an alkyl group having 1 to 3 carbon atoms and one R¹⁰ be a hydrogen atom, and that three R¹¹'s be an alkyl group having 1 to 3 carbon atoms and one R¹¹ be a hydrogen atom; and it is particularly preferable that three R¹⁰'s be a methyl group and one R¹⁰ be a hydrogen atom, and that three R¹¹'s be a methyl group and one R¹¹ be a hydrogen atom.

* represents a bonding site.

In General Formula (a1-3), Z′ represents an alkylene group having 1 to 5 carbon atoms or a divalent aromatic group.

* represents a bonding site.

In General Formula (a1-4), Z² represents a divalent aromatic group, and is preferably a divalent benzene ring. * represents a bonding site.

The negative-type photosensitive polymer of the present embodiment can have at least one structural unit selected from a structural unit (1-1a) represented by General Formula (1-1a) below and a structural unit (1-1b) represented by General Formula (1-1b) below.

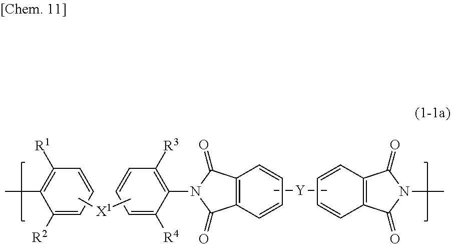

In General Formula (1-1a), R¹ to R⁴ and X¹ have the same definition as those in General Formula (1a), and Y has the same definition as that in General Formula (1-1).

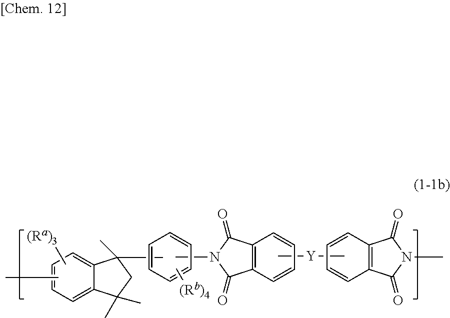

In General Formula (1-1b), R^{a} and R^{b} have the same definitions as those in General Formula (1b), and Y has the same definition as that in General Formula (1-1).

At least one of both terminals of the solvent-soluble negative-type photosensitive polymer can have the group having a terminal double bond at the side chain. When the side chain has the group having a terminal double bond, a structural unit (1-1c) represented by General Formula (1-1c) below can be included.

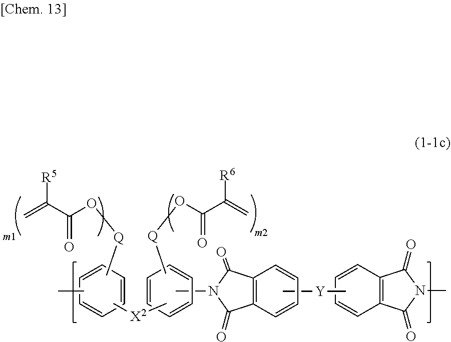

In General Formula (1-1c), R⁵, R⁶, Q, m1, m2, and X² have the same definitions as those in General Formula (1c), and Y has the same definition as that in General Formula (1-1).

In the present embodiment, for example, in the negative-type photosensitive polymer having the structural unit represented by General Formula (1-1) above, the average value of the positive electric charges (δ+) of two carbonyl carbons of the imide ring is measured as follows.

The average value of δ+ of two carbonyl carbons of the imide ring contained in the compound represented by General Formula (1-1′) below, which is measured under the following condition, is calculated.

### [Condition]

The compound represented by General Formula (1-1′) above is measured by a charge equilibration method using soft HSPiP (ver. 5.3), and δ+ of two carbonyl carbons of the imide ring contained in the above-mentioned compound is averaged to obtain the average value.

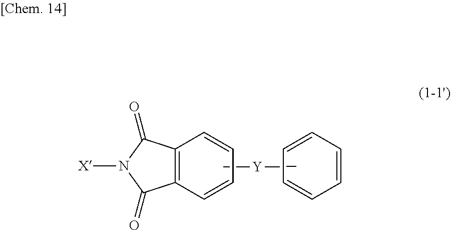

In General Formula (1-1′), Y has the same definition as that in General Formula (1-1). X′ is a monovalent group represented by General Formula (1a-1) below or General Formula (1b-1) below.

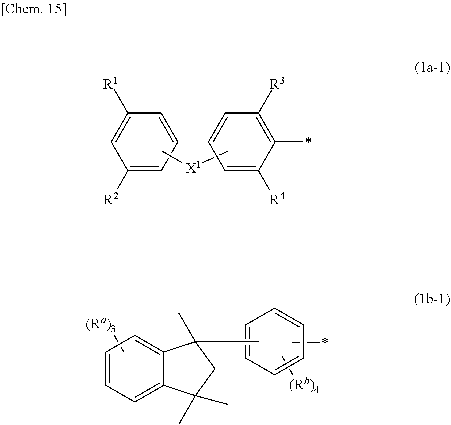

In General Formula (1a-1), R¹ to R⁴ and X¹ have the same definitions as those in General Formula (1a). * represents a bonding site. In General Formula (1b-1), R^{a} and R^{b} have the same definition as those in General Formula (1b). * represents a bonding site.

When the negative-type photosensitive polymer having the structural unit represented by General Formula (1-1) above has a plurality of groups as X, the average value of δ+ is calculated for each possible combination, and the weighted average is taken according to the charging amount to calculate the average value of the positive electric charges (δ+) of two carbonyl carbons of the imide ring.

Specifically, when the negative-type photosensitive polymer having the structural unit represented by General Formula (1-1) has the structural unit (1-1a) having the group of General Formula (1a) as X and the structural unit (1-1b) having the group of General Formula (1b) as X, the compound represented by General Formula (1-1′) above having the group of General Formula (1a-1) is measured by a charge equilibration method using soft HSPiP (ver. 5.3), and δ+ of two carbonyl carbons of the imide ring contained in the above-mentioned compound is averaged to obtain an average value (1). The compound represented by General Formula (1-1′) above having the group of General Formula (1b-1) is measured in the same manner, and δ+ of two carbonyl carbons of the imide ring contained in the above-mentioned compound is averaged to obtain an average value (2). In addition, when the total of the number of moles (1) of the structural unit (1-1a) and the number of moles (2) of the structural unit (1-1b) is set to 100, δ+ is calculated by the following expression.

Expression: [average value (1) of δ+×molar fraction (1)+average value (2) of δ+×molar fraction (2)]/100

Furthermore, when the negative-type photosensitive polymer has the group having a terminal double bond at the side chain, X′ can include a monovalent group represented by General Formula (1c-1) below.

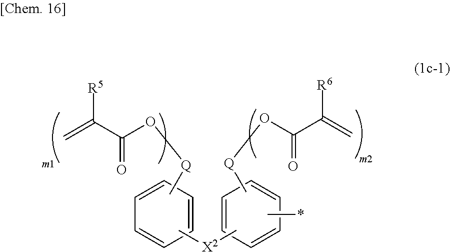

In General Formula (1c-1), R⁵, R⁶, Q, m1, m2, and X² have the same definitions as those in General Formula (1c).

For example, when the negative-type photosensitive polymer having the structural unit represented by General Formula (1-1) has the structural unit (1-1a) having the group of General Formula (1a) as X, the structural unit (1-1b) having the group of General Formula (1b) as X, and the structural unit (1-1c) having the group of General Formula (1c) as X, the compound represented by General Formula (1-1′) above having the group of General Formula (1a-1) is measured by a charge equilibration method using soft HSPiP (ver. 5.3), and δ+ of two carbonyl carbons of the imide ring contained in the above-mentioned compound is averaged to obtain an average value (1). The compound represented by General Formula (1-1′) above having the group of General Formula (1b-1) is measured in the same manner, and δ+ of two carbonyl carbons of the imide ring contained in the above-mentioned compound is averaged to obtain an average value (2). Furthermore, the compound represented by General Formula (1-1′) above having the group of General Formula (1c-1) is measured in the same manner, and δ+ of two carbonyl carbons of the imide ring contained in the above-mentioned compound is averaged to obtain an average value (3). In addition, when the total of the number of moles (1) of the structural unit (1-1a), the number of moles (2) of the structural unit (1-1b), and the number of moles (3) of the structural unit (1-1c) is set to 100, δ+ is calculated by the following expression.

Expression: [average value (1) of δ+×molar fraction (1)+average value (2) of δ+×molar fraction (2)+average value (3) of δ+×molar fraction (3)]/100

When the negative-type photosensitive polymer having the structural unit represented by General Formula (1-1) above has four or more groups as X, as in the same manner described above, the average value of δ+ is calculated for each possible combination, and the weighted average is taken according to the charging amount to calculate the average value of the positive electric charges (δ+) of two carbonyl carbons of the imide ring of the negative-type photosensitive polymer.

When the negative-type photosensitive polymer of the present embodiment has a structure having the above-mentioned structural units and having the group having a terminal double bond at the side chain of the negative-type photosensitive polymer, the negative-type photosensitive polymer may further have the following structural unit partially.

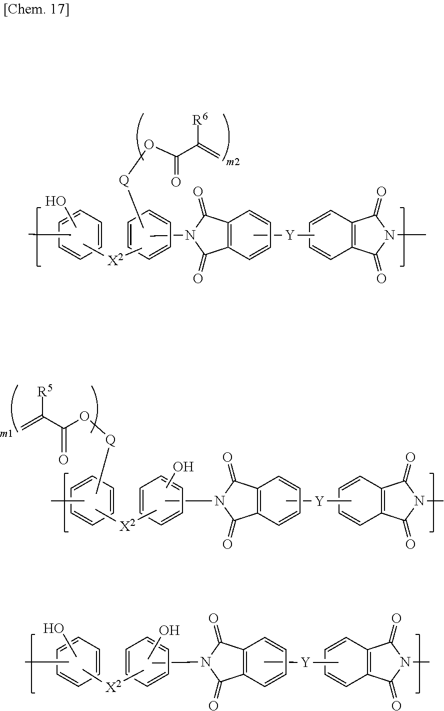

In these general formulas, R⁵, R⁶, Q, m1, m2, and X² have the same definitions as those in General Formula (1c), and Y has the same definition as that in General Formula (1-1).

In the present embodiment, the negative-type photosensitive polymer preferably contains the group having a terminal double bond at at least one of both terminals, and the group is more preferably a (meth)acrylate group. When the group is contained, mechanical strength such as elongation is better.

Whether a (meth)acrylate group is contained can be analyzed by ¹H-NMR.

Specifically, when negative-type photosensitive polymer containing the divalent group represented by General Formula (1c) above contains the group having a terminal double bond at at least one of both terminals, as a terminal structure, the negative-type photosensitive polymer preferably has at least one of a terminal structure (a4) to a terminal structure (a13) represented by General Formula (a4) below to General Formula (a13) below, and more preferably has a terminal structure (a4).

On the other hand, the negative-type photosensitive polymer not containing the divalent group represented by General Formula (1c) above preferably has at least one of the terminal structure (a4) to the terminal structure (a6) represented by General Formula (a4) below to General Formula (a6) below at at least one of both terminals, and more preferably has the terminal structure (a4) at at least one of both terminals.

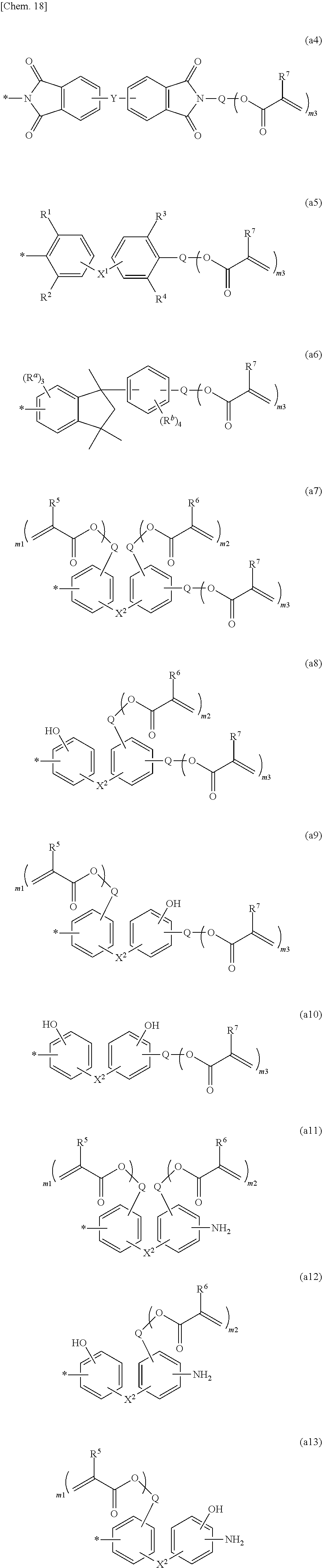

In General Formula (a4), Q has the same definition as that in General Formula (1c), and Y has the same definition as that in General Formula (1-1). R⁷ represents a hydrogen atom, an alkyl group having 1 to 3 carbon atoms, or an alkoxy group having 1 to 3 carbon atoms. m3 represents an integer of 1 to 3. * represents a bonding site.

In General Formula (a5), Q has the same definition as that in General Formula (1c), and X¹ and R¹ to R⁴ have the same definition as those in General Formula (1a). R⁷ and m3 have the same definition as those in General Formula (a4). * represents a bonding site.

In General Formula (a6), Q has the same definition as that in General Formula (1c), and R^{a} and R^{b} have the same definition as those in General Formula (1b). R⁷ and m3 have the same definition as those in General Formula (a4). * represents a bonding site.

In General Formulas (a7) to (a13), Q, R⁵, R⁶, m1, m2, and X² have the same definitions as those in General Formula (1c). R⁷ and m3 have the same definition as those in General Formula (a4). * represents a bonding site.

The weight-average molecular weight of the negative-type photosensitive polymer of the present embodiment is 5,000 to 200,000, and preferably 10,000 to 100,000.

Since the hydrolysis is inhibited in the negative-type photosensitive polymer of the present embodiment, a cured product such as a film having excellent mechanical strength such as elongation can be obtained from the negative-type photosensitive polymer and the negative-type photosensitive resin composition containing the negative-type photosensitive polymer.

In addition, the negative-type photosensitive polymer of the present embodiment has an excellent solubility in a solvent and thus is not required to be in a precursor state when being varnished. Therefore, a varnish containing the negative-type photosensitive polymer can be prepared, which makes it possible to obtain a cured product such as a film from this varnish.

### <Method for Producing Negative-Type Photosensitive Polymer>

### First Embodiment

A method for producing the negative-type photosensitive polymer having the group having a terminal double bond at the side chain will be described.

For example, a method for producing the negative-type photosensitive polymer having the structural unit (1-1a) and/or the structural unit (1-1b), and the structural unit (1-1c) includes the following steps:
A step 1 of imidizing an acid anhydride (i) represented by General Formula (i) below, a diamine (ii) represented by General Formula (ii) below and/or a diamine (iii) represented by General Formula (iii) below, and a bisaminophenol (iv) represented by General Formula (iv) below at a temperature of equal to or higher than 100° C. and equal to or lower than 250° C.; and
A step 2 of reacting a compound having a (meth)acrylate group with the hydroxyl group having the structural unit derived from the bisaminophenol (iv) of General Formula (iv) above of the polymer obtained in the step 1 to introduce a group having a (meth)acrylate group.

According to the present embodiment, the negative-type photosensitive polymer having excellent solvent solubility can be synthesized by a simple method.

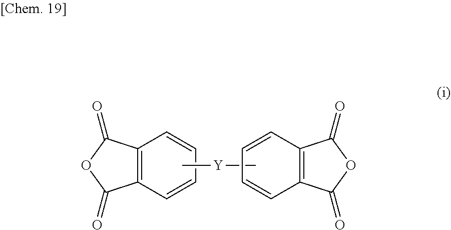

In General Formula (i), Y has the same definition as that in General Formula (1-1), and is preferably selected from the group represented by General Formula (a1-1), (a1-2), (a1-3), or (a1-4) above.

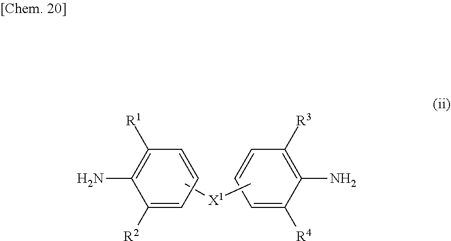

In General Formula (ii), R¹ to R⁴ and X¹ have the same definitions as those in General Formula (1a).

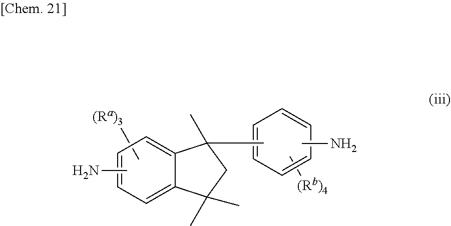

In General Formula (iii), R^{a} and R^{b} have the same definition as those in General Formula (1b).

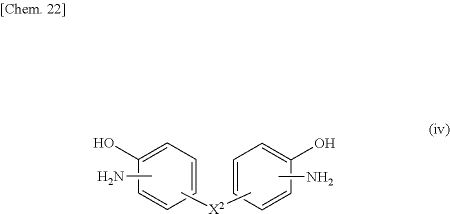

In General Formula (iv), X² has the same definition as that in General Formula (1c).

The reaction can also be caused by adding a small amount of acid anhydride or aromatic amine as an end-cap agent to control the molecular weight of the obtained polyhydroxyimide.

Examples of the acid anhydrides as the end-cap agent include phthalic acid anhydride, maleic acid anhydride, and nadic acid anhydride. Examples of the aromatic amines include p-methylaniline, p-methoxyaniline, and p-phenoxyaniline. The addition amount of the acid anhydride or the aromatic amine as the end-cap agent is preferably equal to or less than 5 mol %. When the addition amount is more than 5 mol %, the molecular weight of the obtained polyhydroxyimide is significantly lowered, which causes problems in heat resistance and mechanical characteristics.

The equivalent ratio of the acid anhydride (i), the diamine (ii) and/or the diamine (iii), and the bisaminophenol (iv) in the imidization reaction of the step 1 is an important factor when determining the molecular weight of the obtained polymer. In general, it is well known that there is a correlation between the molecular weight and the mechanical properties of a polymer, and the higher the molecular weight the better the mechanical properties. Accordingly, a molecular weight that is high to a certain degree is required to obtain a polymer having a practically excellent strength. In the present invention, the equivalent ratio of the acid anhydride (i) used, the diamine (ii) and/or the diamine (iii) used, and the bisaminophenol (iv) used is not particularly limited, but the equivalent ratio of the diamine (ii) and/or the diamine (iii), and the bisaminophenol (iv) to the acid anhydride (i) is preferably within a range of 0.70 to 1.30. When the equivalent ratio is within the above-mentioned range, the mechanical strength is excellent, and the production stability is excellent.

From the viewpoint of improving the mechanical properties, even when the equivalent ratio of the diamine (ii) and/or the diamine (iii), and the bisaminophenol (iv) to the acid anhydride (i) is outside the above-mentioned range, the apparent molecular weight can also be increased by side-chain crosslinking of the resin.

The step 1 (imidization reaction step) can be carried out in an organic solvent by a known method.

Examples of the organic solvents include polar aprotic solvents such as γ-butyrolactone (GBL), N,N-dimethylformamide, N,N-dimethylacetamide, tetrahydrofuran, diethylene glycol dimethyl ether, diethylene glycol diethyl ether, cyclohexanone, and 1,4-dioxane, and one type or a combination of two or more types may be used. At this time, a non-polar solvent that is compatible with the above-mentioned polar aprotic solvent may be mixed and used. Examples of the non-polar solvents include aromatic hydrocarbons such as toluene, ethylbenzene, xylene, mesitylene, and solvent naphtha; and ether-based solvents such as cyclopentyl methyl ether. The proportion of the non-polar solvent in the mixed solvent can be arbitrarily set according to a stirring device ability and resin properties such as a solution viscosity as long as the proportion is not within a range in which the degree of solubility of the solvent decreases to the extent that a polyamide acid resin obtained by the reaction precipitates.

Regarding the reaction temperature, a reaction is caused for about 30 minutes to 2 hours at equal to or higher than 0° C. and equal to or lower than 100° C., preferably at equal to or higher than 20° C. and equal to or lower than 80° C., and thereafter a reaction is caused for about 1 hour to 5 hours at equal to or higher than 100° C. and equal to or lower than 250° C., preferably at equal to or higher than 120° C. and equal to or lower than 200° C.

By the step 1, a polyhydroxyimide having the structural unit (1-1a) and/or the structural unit (1-1b) and having a structural unit (1-1d) represented by General Formula (1-1d) below can be obtained. In the step 1, the polyhydroxyimide can be purified by a known method; however, the step 1 and the step 2 can be continuously carried out without purifying the obtained polyhydroxyimide by improving the dehydration efficiency in polymerization.

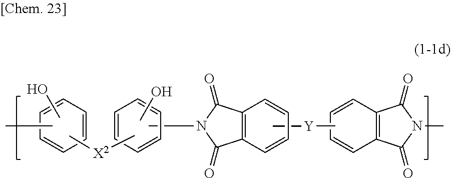

In General Formula (1-1d), X² has the same definition as that in General Formula (1c), and Y has the same definition as that in General Formula (1-1) and is preferably selected from the group represented by General Formula (a1-1), (a1-2), (a1-3), or (a1-4) above.

In the step 2, a compound having a (meth)acrylate group is reacted with the hydroxyl group of the polyhydroxyimide obtained by the step 1 to introduce a crosslinking group including the (meth)acrylate group.

The crosslinking group introduced into the negative-type photosensitive polymer (A) reacts with a crosslinking agent (B) to be described later in an exposure step, thereby making the exposed portion insoluble in an organic solvent.

Examples of the compounds having a (meth)acrylate group include 2-isocyanatoethyl (meth)acrylate, 2-(2-(meth)acryloyloxyethyloxy)ethyl isocyanate, 1,1-(bisacryloyloxymethyl)ethyl isocyanate, glycidyl methacrylate, and 4-hydroxybutyl acrylate glycidyl ether.

The polyhydroxyimide and the compound having a (meth)acrylate group are reacted at 60° C. to 150° C. for about 2 to hours while being mixed in an organic solvent to introduce the crosslinking group including a (meth)acrylate group into the polyhydroxyimide. The reaction can be carried out at normal pressure although there is no particular limitation.

The addition amount of the compound having a (meth)acrylate group can be appropriately selected according to the amount of crosslinking groups introduced into the polyhydroxyimide, but can be 0.8 to 3.0 times by mol, preferably 2.0 to 3.0 times by mol, for example, with respect to the molar amount of the hydroxyl group in the polyhydroxyimide. When the polyhydroxyimide has a group capable of introducing a crosslinking group, this group can be added to the molar amount.

Examples of the organic solvents include polar aprotic solvents such as γ-butyrolactone (GBL), N,N-dimethylformamide, N,N-dimethylacetamide, tetrahydrofuran, diethylene glycol dimethyl ether, diethylene glycol diethyl ether, cyclohexanone, and 1,4-dioxane, and one type or a combination of two or more types may be used. At this time, a non-polar solvent that is compatible with the above-mentioned polar aprotic solvent may be mixed and used. Examples of the non-polar solvents include aromatic hydrocarbons such as toluene, ethylbenzene, xylene, mesitylene, and solvent naphtha; and ether-based solvents such as cyclopentyl methyl ether.

At the time of the reaction, a base such as triethylamine and 1,1,3,3-tetramethylguanidine can also be added.

By the step 2, a negative-type photosensitive polymer having the structural unit (1-1a) and/or the structural unit (1-1b) and having the structural unit (1-1c) can be obtained. In the step 2, a reaction solution containing the polyhydroxyimide obtained in the step 1 can be purified by redeposition or the like to use the obtained polyhydroxyimide, but the reaction solution of the step 1 can be used as it is in the step 2.

By the above production method of the present embodiment, the reaction solution containing the negative-type photosensitive polymer of the present embodiment can be obtained. Furthermore, as necessary, the reaction solution can be diluted with an organic solvent or the like to be used as a polymer solution (varnish for coating). As the organic solvent, those exemplified in the reaction step can be used, and the organic solvent may be the same organic solvent as in the reaction step or may be a different organic solvent.

In addition, a resultant product, which is obtained by putting this reaction solution into a poor solvent to cause redeposition precipitation of the negative-type photosensitive polymer, removing unreacted monomers, and drying to solidify, can be dissolved again in an organic solvent to be used as a purified product. Particularly in usage in which impurities and foreign materials are problematic, it is preferable to carry out dissolution in an organic solvent again to obtain a filtration-purified varnish.

### Second Embodiment

A method for producing the negative-type photosensitive polymer containing the group having a terminal double bond at at least one of both terminals will be described.

The negative-type photosensitive polymer can be performed by the same method as that of the first embodiment except that the bisaminophenol (iv) represented by General Formula (iv) above is not used.

In the present embodiment, the equivalent ratio of the acid anhydride (i) used, and the diamine (ii) and/or the diamine (iii) used is not particularly limited, the equivalent ratio of the diamine (ii) and/or the diamine (iii) with respect to the acid anhydride (i) is preferably within a range of 0.70 to 1.30. When the equivalent ratio is less than 0.70, the molecular weight is low, and brittleness is caused, resulting in a low mechanical strength. In addition, when the equivalent ratio is more than 1.30, the molecular weight is low, and brittleness is caused, resulting in a low mechanical strength. In other words, when the equivalent ratio is within the above-mentioned range, the mechanical strength is excellent, and the production stability is excellent.

### [Characteristics of Negative-Type Photosensitive Polymer]

The negative-type photosensitive polymer of the present embodiment has excellent solvent solubility, and equal to or more than 5% by mass thereof can be dissolved particularly in γ-butyrolactone (GBL).

The negative-type photosensitive polymer of the present embodiment is solvent-soluble, and thus can be suitably used as a polymer solution (varnish).

The negative-type photosensitive polymer of the present embodiment has excellent hydrolysis resistance, and the reduction rate of the weight-average molecular weight thereof measured under the following conditions is equal to or less than 15%, and preferably equal to or less than 12%.

### (Condition)

When 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression.

Expression: [(weight-average molecular weight before test−weight-average molecular weight after test)/weight-average molecular weight before test]×100

When the reduction rate of the weight-average molecular weight of the negative-type photosensitive polymer of the present embodiment is within the above-mentioned range, it is possible to obtain a cured product such as a film having excellent mechanical strength such as elongation.

Table A below shows preferable blending examples of the negative-type photosensitive polymer of the present embodiment.

TABLE A

| | Diamine | Bis(amino- | Acid | Acrylic |
|---|---|---|---|---|
| | compound | phenol) | anhydride | compound |
| Blending | MED-J | BAPA | TMPBP- | AOI (side chain |
| Example 1 | | | TME | introduction) |
| Blending | MED-J | Not used | TMPBP- | AOI (terminal |
| Example 2 | | | TME | introduction) |
| Blending | MED-J | BAPA | TMHQ | AOI (side chain |
| Example 3 | | | | introduction) |
| Blending | MED-J | BAPA | TMPBP- | MOI (side chain |
| Example 4 | | | TME | introduction) |
| Blending | TMDA | BAPA | TMPBP- | AOI (side chain |
| Example 5 | | | TME | introduction) |
| Blending | TMDA | Not used | TMPBP- | AOI (terminal |
| Example 6 | | | TME | introduction) |
| Blending | TMDA | BAPA | TMHQ | AOI (side chain |
| Example 7 | | | | introduction) |
| Blending | TMDA | BAPA | TMPBP- | MOI (side chain |
| Example 8 | | | TME | introduction) |
| Blending | BTFL | BAPA | TMPBP- | AOI (side chain |
| Example 9 | | | TME | introduction) |
| Blending | BTFL | Not used | TMPBP- | AOI (terminal |
| Example 10 | | | TME | introduction) |
| Blending | BTFL | BAPA | TMHQ | AOI (side chain |
| Example 11 | | | | introduction) |
| Blending | BTFL | BAPA | TMPBP- | MOI (side chain |
| Example 12 | | | TME | introduction) |

MED-J: 4,4-diamino-3,3-diethyl-5,5-dimethyldiphenylmethane
TMDA: mixture of 1-(4-aminophenyl)-1,3,3-trimethylphenylindan-6-amine and 1-(4-aminophenyl)-1,3,3-trimethylphenylindan-5-amine
BTFL: 9,9-bis(3-methyl-4-aminophenyl)fluorene
BAPA: 2,2-bis(3-amino-4-hydroxyphenyl)propane
TMPBP-TME: 4-[4-(1,3-dioxoisobenzofuran-5-ylcarbonyloxy)-2,3,5-trimethylphenyl]-2,3,6-trimethylphenyl 1,3-dioxoisobenzofuran-5-carboxylate
TMHQ: p-phenylenebis (trimellitate anhydride)
AOI: 2-isocyanatoethyl acrylate
MOI: 2-isocyanatoethyl methacrylate

### <Negative-Type Photosensitive Resin Composition>

A negative-type photosensitive resin composition of the present embodiment contains (A) the above-mentioned negative-type photosensitive polymer, (B) a crosslinking agent containing a polyfunctional (meth)acrylate, and (C) a photopolymerization initiator.

### [Crosslinking Agent (B)]

The crosslinking agent (B) contains a polyfunctional (meth)acrylate.

The polyfunctional (meth)acrylate is a compound having two or more (meth)acryloyl groups, and conventionally known compounds can be used as long as the effects of the present invention can be exhibited. In the present embodiment, the (meth)acrylic group refers to an acrylic group or a methacrylic group.

Specific examples of the polyfunctional (meth)acrylates include difunctional (meth)acrylates such as diethylene glycol di(meth)acrylate, polyethylene glycol #200 di(meth)acrylate, and polyethylene glycol #400 di(meth)acrylate; trifunctional (meth)acrylates such as trimethylolpropane tri(meth)acrylate, pentaerythritol tri(meth)acrylate, and ethoxylated isocyanuric acid triacrylate; tetrafunctional (meth)acrylates such as pentaerythritol tetra(meth)acrylate and ditrimethylolpropane tetra(meth)acrylate; hexafunctional (meth)acrylates such as dipentaerythritol hexa(meth)acrylate; octafunctional (meth)acrylates such as tripentaerythritol octa(meth)acrylate; and decafunctional (meth)acrylates such as tetrapentaerythritol deca(meth)acrylate. Among these, one type or two or more types may be used.

From the viewpoint of the effects of the present invention, the amount of the crosslinking agent (B) with respect to 100 parts by mass of the negative-type photosensitive polymer (A) can be set to equal to or more than 1 part by mass and equal to or less than 30 parts by mass, preferably equal to or more than 2 parts by mass and equal to or less than 20 parts by mass, and preferably equal to or more than 3 parts by mass and equal to or less than 15 parts by mass. Within the above range, the elongation is further enhanced.

### [Photopolymerization Initiator (C)]

As the photopolymerization initiator (C), a photoradical generator can be used, for example. The photoradical generator includes a photoradical generator that functions as a photopolymerization initiator for the above-mentioned negative-type photosensitive polymer (A) by generating radicals upon irradiation with actinic rays such as ultraviolet rays.

Examples of the above-mentioned photoradical generators include alkyl phenone type initiators, oxime ester type initiators, and acyl phosphine oxide type initiators. Examples thereof include 1-hydroxycyclohexyl phenyl ketone, 2,2-dimethoxy-1,2-diphenylethan-1-one, 2-methyl-1[4-(methylthio)phenyl]-2-morpholinopropan-1-one, 2-hydroxy-2-methyl-1-phenylpropan-1-one, 1-[4-(2-hydroxyethoxy)-phenyl]-2-hydroxy-2-methyl-1-propan-1-one, bis(2,4,6-trimethylbenzoyl)-phenylphosphine oxide, 1,2-octanedione, 1-[4-(phenylthio)-, 2-(O-benzoyloxime)), ethanone, 1-[9-ethyl-6-(2-methylbenzoyl)-9H-carbazol-3-yl]-, 1-(0-acetyloxime), 2-(dimethylamino)-1-(4-(4-morpholino)phenyl)-2-(phenylmethyl)-1-butanone, Irgacure Oxe01 (BASF Japan Ltd.), Irgacure Oxe02 (BASF Japan Ltd.), Irgacure Oxe03 (BASF Japan Ltd.), Irgacure Oxe04 (BASF Japan Ltd.), N-1919T (ADEKA Corporation), NCI-730 (ADEKA Corporation), NCI-831E (ADEKA Corporation), and NCI-930 (ADEKA Corporation). Any one or more of these can be used.

Among these, oxime ester type initiators are preferable from the viewpoint of the effects of the present invention and from the viewpoint of producing a resin film composed of a photosensitive resin composition having better exposure sensitivity.

The addition amount of the polymerization initiator (C) is not particularly limited, but is preferably about 0.3% to 20% by mass, is more preferably about 0.5% to 15% by mass, and is further preferably about 1% to 10% by mass of 100% by mass of non-volatile components excluding the solvent of the negative-type photosensitive resin composition. By setting the addition amount of the polymerization initiator (C) within the above-mentioned range, the patterning properties of a photosensitive resin layer containing the negative-type photosensitive resin composition can be improved, and also, the long-term storability of the negative-type photosensitive resin composition can be improved.

### (Solvent)

The negative-type photosensitive resin composition according to the present embodiment can contain a solvent. Thus, a uniform photosensitive resin film can be formed on the surfaces of various substrates.

As the solvent, an organic solvent is preferably used. Specifically, one or two or more of a ketone-based solvent, an ester-based solvent, an ether-based solvent, an alcohol-based solvent, a lactone-based solvent, a carbonate-based solvent, and the like can be used.

Examples of the solvents include propylene glycol monomethyl ether (PGME), propylene glycol monomethyl ether acetate (PGMEA), ethyl lactate, methyl isobutyl carbinol (MIBC), gamma-butyrolactone (GBL), N-methylpyrrolidone (NMP), methyl-n-amyl ketone (MAK), diethylene glycol monomethyl ether, diethylene glycol dimethyl ether, diethylene glycol methyl ethyl ether, cyclohexanone, and mixtures thereof.

The use amount of the solvent is not particularly limited. For example, the solvent is used in amounts such that the concentration of the non-volatile components is 10% to 70% by mass, and preferably 15% to 60% by mass, for example.

### (Surfactant)

The negative-type photosensitive resin composition according to the present embodiment may further contain a surfactant.

A surfactant is not particularly limited, and specific examples thereof include polyoxyethylene alkyl ethers such as polyoxyethylene lauryl ether, polyoxyethylene stearyl ether, and polyoxyethylene oleyl ether; polyoxyethylene aryl ethers such as polyoxyethylene octylphenyl ether and polyoxyethylene nonylphenyl ether; nonionic surfactants such as polyoxyethylene dialkyl esters such as polyoxyethylene dilaurate and polyoxyethylene distearate; F-TOP EF301, F-TOP EF303, and F-TOP EF352 (manufactured by Shin Akita Kasei Co., Ltd.); MEGAFACE F171, MEGAFACE F172, MEGAFACE F173, MEGAFACE F177, MEGAFACE F444, MEGAFACE F470, MEGAFACE F471, MEGAFACE F475, MEGAFACE F482, and MEGAFACE F477 (manufactured by DIC Corporation); Fluorad FC-430, Fluorad FC-431, Novec FC4430, and Novec FC4432 (manufactured by 3M Japan Ltd.); fluorine-based surfactants commercially available under names such as SURFLON S-381, SURFLON S-382, SURFLON S-383, SURFLON S-393, SURFLON SC-101, SURFLON SC-102, SURFLON SC-103, SURFLON SC-104, SURFLON SC-105, and SURFLON SC-106 (manufactured by AGC SEIMI CHEMICAL CO., LTD.); an organosiloxane copolymer KP341 (manufactured by Shin-Etsu Chemical Co., Ltd.); and a (meth)acrylic acid copolymer Polyflow Nos. 57 and 95 (manufactured by KYOEISHA CHEMICAL CO., LTD.).

Among these, a fluorine-based surfactant having a perfluoroalkyl group is preferably used. Among the above-mentioned specific examples, as the fluorine-based surfactant having a perfluoroalkyl group, it is preferable to use one or two or more selected from MEGAFACE F171, MEGAFACE F173, MEGAFACE F444, MEGAFACE F470, MEGAFACE F471, MEGAFACE F475, MEGAFACE F482, and MEGAFACE F477 (manufactured by DIC Corporation); SURFLON S-381, SURFLON S-383, and SURFLON S-393 (manufactured by AGC SEIMI CHEMICAL CO., LTD.); and Novec FC4430 and Novec FC4432 (manufactured by 3M Japan Ltd.).

In addition, as the surfactant, a silicone-based surfactant (such as polyether-modified dimethylsiloxane) can also be preferably used. Specific examples of the silicone-based surfactants include SH series, SD series, and ST series of Dow Corning Toray Co., Ltd.; BYK series of BYK-Chemie Japan K. K.; KP series of Shin-Etsu Chemical Co., Ltd.; DISFOAM (registered trademark) series of NOF CORPORATION; and TSF series of Toshiba Silicones Co., Ltd.

The upper limit value of the content of the surfactant in the negative-type photosensitive resin composition is preferably equal to or less than 1% by mass (10,000 ppm), more preferably equal to or less than 0.5% by mass (5,000 ppm), and further preferably equal to or less than 0.1% by mass (1,000 ppm) with respect to the entirety (including the solvent) of the negative-type photosensitive resin composition.

In addition, the lower limit value of the content of the surfactant in the negative-type photosensitive resin composition is not particularly limited, but is equal to or more than 0.001% by mass (10 ppm), for example, with respect to the entirety (including the solvent) of the negative-type photosensitive resin composition from the viewpoint of sufficiently obtaining the effect of the surfactant.

By appropriately adjusting the amount of the surfactant, the applicability, the uniformity of a coating film, and the like can be enhanced while maintaining the other performances.

### (Antioxidant)

The negative-type photosensitive resin composition according to the present embodiment may further contain an antioxidant. As the antioxidant, it is possible to use one or more selected from a phenol-based antioxidant, a phosphorus-based antioxidant, and a thioether-based antioxidant. The antioxidant can inhibit the oxidation of a resin film formed from the negative-type photosensitive resin composition.

Examples of the phenol-based antioxidants include pentaerythrityl-tetrakis [3-(3,5-di-t-butyl-4-hydroxyphenyl) propionate], 3,9-bis {2-[3-(3-t-butyl-4-hydroxy-5-methylphenyl) propionyloxy]-1,1-dimethylethyl}2,4,8,10-tetraoxaspiro [5,5]undecane, octadecyl-3-(3,5-di-t-butyl-4-hydroxyphenyl) propionate, 1,6-hexanediol-bis [3-(3,5-di-t-butyl-4-hydroxyphenyl) propionate], 1,3,5-trimethyl-2,4,6-tris(3,5-di-t-butyl-4-hydroxybenzyl)benzene, 2,6-di-t-butyl-4-methylphenol, 2,6-di-t-butyl-4-ethylphenol, 2,6-diphenyl-4-octadecyloxyphenol, stearyl (3,5-di-t-butyl-4-hydroxyphenyl) propionate, distearyl (3,5-di-t-butyl-4-hydroxybenzyl)phosphonate, thiodiethylene glycol bis [(3,5-di-t-butyl-4-hydroxyphenyl) propionate], 4,4′-thiobis(6-t-butyl-m-cresol), 2-octylthio-4,6-di(3,5-di-t-butyl-4-hydroxyphenoxy)-s-triazine, 2,2′-methylenebis(4-methyl-6-t-butyl-6-butylphenol), 2,-2′-methylenebis(4-ethyl-6-t-butylphenol), bis [3,3-bis(4-hydroxy-3-t-butylphenyl) butyric acid]glycol ester, 4,4′-butylidenebis(6-t-butyl-m-cresol), 2,2′-ethylidenebis(4,6-di-t-butylphenol), 2,2′-ethylidenebis(4-s-butyl-6-t-butylphenol), 1,1,3-tris(2-methyl-4-hydroxy-5-t-butylphenyl) butane, bis [2-t-butyl-4-methyl-6-(2-hydroxy-3-t-butyl-5-methylbenzyl)phenyl]terephthalate, 1,3,5-tris(2,6-dimethyl-3-hydroxy-4-t-butylbenzyl) isocyanurate, 1,3,5-tris(3,5-di-t-butyl-4-hydroxybenzyl)-2,4,6-trimethylbenzene, 1,3,5-tris [(3,5-di-t-butyl-4-hydroxyphenyl) propionyloxyethyl]isocyanurate, tetrakis [methylene-3-(3,5-di-t-butyl-4-hydroxyphenyl) propionate]methane, 2-t-butyl-4-methyl-6-(2-acryloyloxy-3-t-butyl-5-methylbenzyl) phenol, 3,9-bis(1,1-dimethyl-2-hydroxyethyl)-2, 4-8,10-tetraoxaspiro [5,5]undecane-bis [β-(3-t-butyl-4-hydroxy-5-methylphenyl) propionate], triethylene glycol bis [3-(3-t-butyl-4-hydroxy-5-methylphenyl) propionate], 1,1′-bis(4-hydroxyphenyl)cyclohexane, 2,2′-methylenebis(4-methyl-6-t-butylphenol), 2,2′-methylenebis(4-ethyl-6-t-butylphenol), 2,2′-methylenebis(6-(1-methylcyclohexyl)-4-methylphenol), 4,4′-butylidenebis(3-methyl-6-t-butylphenol), 3,9-bis(2-(3-t-butyl-4-hydroxy-5-methylphenylpropionyloxy) 1,1-dimethylethyl)-2,4,8,10-tetraoxaspiro(5,5) undecane, 4,4′-thiobis(3-methyl-6-t-butylphenol), 4,4′-bis(3,5-di-t-butyl-4-hydroxybenzyl) sulfide, 4,4′-thiobis(6-t-butyl-2-methylphenol), 2,5-di-t-butylhydroquinone, 2,5-di-t-amylhydroquinone, 2-t-butyl-6-(3-t-butyl-2-hydroxy-5-methylbenzyl)-4-methylphenylacrylate, 2,4-dimethyl-6-(1-methylcyclohexyl, styrenated phenol, and 2,4-bis((octylthio)methyl)-5-methylphenol.

Examples of the phosphorus-based antioxidants include bis(2,6-di-t-butyl-4-methylphenyl) pentaerythritol diphosphite, tris(2,4-di-t-butylphenyl phosphite), tetrakis(2,4-di-t-butyl-5-methylphenyl)-4,4′-biphenylene diphosphonite, 3,5-di-t-butyl-4-hydroxybenzylphosphonate diethyl ester, bis-(2,6-dicumylphenyl) pentaerythritol diphosphite, 2,2-methylenebis(4,6-di-t-butylphenyl) octyl phosphite, tris(mono- and di-nonylphenyl mixed phosphite), bis(2,4-di-t-butylphenyl) pentaerythritol diphosphite, bis(2,6-di-t-butyl-4-methoxycarbonylethyl-phenyl) pentaerythritol diphosphite, and bis(2,6-di-t-butyl-4-octadecyloxycarbonylethylphenyl) pentaerythritol diphosphite.

Examples of the thioether-based antioxidants include dilauryl-3,3′-thiodipropionate, bis(2-methyl-4-(3-n-dodecyl)thiopropionyloxy)-5-t-butylphenyl) sulfide, distearyl-3,3′-thiodipropionate, and pentaerythritol-tetrakis(3-lauryl)thiopropionate.

### (Adhesion Aid)

The negative-type photosensitive resin composition according to the present embodiment may further contain an adhesion aid.

As the adhesion aid, for example, it is possible to use a silane coupling agent such as aminosilane, epoxysilane, (meth)acrylic silane, mercaptosilane, vinylsilane, ureidosilane, acid anhydride-functional silane, and sulfidesilane. For the silane coupling agent, one type may be used alone, and two or more types may be used in combination. Among these, epoxysilane (that is, a compound containing, in one molecule, both an epoxy moiety and a group that generates a silanol group by hydrolysis) or acid anhydride-functional silane (that is, a compound containing, in one molecule, both an acid anhydride group and a group that generates a silanol group by hydrolysis) is preferable.

Examples of aminosilanes include bis(2-hydroxyethyl)-3-aminopropyltriethoxysilane, γ-aminopropyltriethoxysilane, γ-aminopropyltrimethoxysilane, γ-aminopropylmethyldiethoxysilane, γ-aminopropylmethyldimethoxysilane, N-(aminoethyl) γ-aminopropyltrimethoxysilane, N-β (aminoethyl) γ-aminopropyltriethoxysilane, N-β (aminoethyl) γ-aminopropylmethyldimethoxysilane, N-β (aminoethyl) γ-aminopropylmethyldiethoxysilane, and N-phenyl-γ-amino-propyltrimethoxysilane.

Examples of epoxysilanes include γ-glycidoxypropyltrimethoxysilane, γ-glycidoxypropylmethyldiethoxysilane, β-(3,4-epoxycyclohexyl)ethyltrimethoxysilane, and γ-glycidylpropyltrimethoxysilane.

Examples of acrylsilanes include γ-(methacryloxypropyl) trimethoxysilane, γ-(methacryloxypropyl)methyldimethoxysilane, and γ-(methacryloxypropyl)methyldiethoxysilane.

Examples of mercaptosilanes include 3-mercaptopropyltrimethoxysilane.

Examples of vinylsilanes include vinyltris(β-methoxyethoxy) silane, vinyltriethoxysilane, and vinyltrimethoxysilane.

Examples of ureidosilanes include 3-ureidopropyltriethoxysilane.

Examples of the acid anhydride-functional silanes include X-12-967C (trade name) (compound name: 3-trimethoxysilyl propylsuccinic anhydride) manufactured by Shin-Etsu Chemical Co., Ltd.

Examples of sulfidesilanes include bis(3-(triethoxysilyl) propyl) disulfide and bis(3-(triethoxysilyl) propyl) tetrasulfide.

The addition amount of the adhesion aid is not particularly limited, but is 0.1% to 5% by mass, and preferably 0.5% to 3% by mass of the total solid content of the negative-type photosensitive resin composition.

### (Preparation of Negative-Type Photosensitive Resin Composition)

A method for preparing the negative-type photosensitive resin composition of the present embodiment is not limited, and known methods can be used according to the components contained in the negative-type photosensitive resin composition.

For example, the preparation can be performed by mixing and dissolving each of the above-mentioned components in a solvent.

### (Cured Film)

The negative-type photosensitive resin composition according to the present embodiment is used as follows: the negative-type photosensitive resin composition is applied to a surface containing a metal such as Al or Cu; subsequently, drying is performed by pre-baking to form a resin film; subsequently, the resin film is patterned into a desired shape by exposure and development; and subsequently, the resin film is cured by a heat treatment to form a cured film.

Furthermore, when manufacturing the above-mentioned permanent film, as the pre-baking condition, the heat treatment can be performed at a temperature equal to or higher than 90° C. and equal to or lower than 130° C. for equal to or longer than 30 seconds and equal to or shorter than 1 hour, for example. Furthermore, regarding the heat treatment condition, for example, the heat treatment can be performed at a temperature equal to or higher than 150° C. and equal to or lower than 250° C. for equal to or longer than 30 minutes and equal to or shorter than 10 hours, and preferably, the heat treatment can be performed at about 170° C. for 1 to 6 hours.

In a film obtained from the negative-type photosensitive resin composition of the present embodiment, a maximum value of an elongation percentage measured by a tensile test using a TENSILON tester is 15% to 200%, preferably 20% to 150%, and an average value thereof is 10% to 150%, preferably 15% to 120%.

In the film obtained from the negative-type photosensitive resin composition of the present embodiment, a tensile strength measured by a tensile test using a TENSILON tester is preferably equal to or more than 20 MPa, and more preferably 30 to 300 MPa.

In addition, since the negative-type photosensitive resin composition of the present embodiment contains the negative-type photosensitive polymer (A) having excellent hydrolysis resistance, even after carrying out a HAST test (unsaturated pressurized steam test) for 96 hours at a temperature of 130° C. and a relative humidity of 85% RH, the rate of decrease in the elongation percentage (maximum value and average value) expressed by the following expression is equal to or less than 20%, preferably equal to or less than 15%, and more preferably equal to or less than 12%.

[(Elongation percentage before test-elongation percentage after test)/elongation percentage before test)]×100

The negative-type photosensitive resin composition of the present embodiment has excellent low-temperature curing properties.

For example, the glass transition temperature (Tg) of a cured product obtained by curing the negative-type photosensitive resin composition of the present embodiment at 170° C. for 4 hours can be set to equal to or higher than 200° C., preferably equal to or higher than 210° C., and more preferably equal to or higher than 220° C.

Furthermore, the storage elastic modulus E′ at 30° C. of the cured product obtained by curing the negative-type photosensitive resin composition of the present embodiment at 170° C. for 4 hours can be set to equal to or more than 2.0 GPa, preferably equal to or more than 2.5 GPa, and further preferably equal to or more than 3.0 GPa. Furthermore, the storage elastic modulus E′ at 200° C. can be set to equal to or more than 0.5 GPa, preferably equal to or more than 0.7 GPa, and more preferably equal to or more than 0.8 GPa.

The viscosity of the negative-type photosensitive resin composition according to the present embodiment can be appropriately set according to a desired thickness of the resin film. The viscosity of the negative-type photosensitive resin composition can be adjusted by adding a solvent.

A cured product such as a film obtained from the negative-type photosensitive resin composition of the present embodiment has excellent chemical resistance.

Specifically, a film is immersed at 40° C. for 10 minutes in a solution of less than 99% by mass of dimethyl sulfoxide and less than 2% by mass of tetramethylammonium hydroxide, thereafter thoroughly cleaned with isopropyl alcohol, and thereafter air-dried to measure the film thickness after the treatment. The rate of change in the film thickness after the treatment and the film thickness before the treatment is calculated by the following formula, and the loss rate of the film is evaluated.

Formula: loss rate (%) of film {(film thickness after immersion−film thickness before immersion)/film thickness before immersion×100(%)}

The rate of change in the film thickness is preferably equal to or less than 40%, and more preferably equal to or less than 30%. Accordingly, even when the cured film is subjected to a step of being immersed in dimethyl sulfoxide, the film thickness is little reduced. Therefore, the cured film that can maintain functions even after being subjected to such a step can be obtained.

Because cure shrinkage is prevented in the negative-type photosensitive resin composition of the present embodiment, in a case where the film is prepared by spin coating a silicon wafer surface such that the film thickness after drying is 10 μm to perform pre-baking at 120° C. for 3 minutes, thereafter performing exposure to 600 mJ/cm² using a high-pressure mercury lamp, and thereafter performing a heat treatment at 170° C. for 120 minutes in a nitrogen atmosphere, the cure shrinkage ratio calculated from the following formula with the film thickness after the above-mentioned pre-baking as a film thickness A and the film thickness after the above-mentioned heat treatment as a film thickness B can be set to preferably equal to or less than 12%, and more preferably equal to or less than 10%.

Formula: cure shrinkage ratio [%]={(film thickness A−film thickness B)/film thickness A}×100

The negative-type photosensitive resin composition of the present embodiment has high heat resistance, and thus in the obtained film, a weight loss temperature (Td5) measured by thermogravimetry-differential thermal analysis can be set to equal to or higher than 200° C., and preferably equal to or higher than 300° C.

The cure shrinkage is prevented in the film formed from the negative-type photosensitive resin composition of the present embodiment, and thus the coefficient of linear thermal expansion (CTE) can be set to equal to or less than 200 ppm/° C., and preferably equal to or less than 100 ppm/° C.

The film formed from the negative-type photosensitive resin composition of the present embodiment has an excellent mechanical strength, and thus an elastic modulus at 25° C. can be set to 1.0 to 5.0 GPa, and preferably 1.5 to 3.0 GPa.

### (Usage)

The negative-type photosensitive resin composition of the present embodiment is used for forming a resin film for a semiconductor device such as a permanent film and a resist. Among these, the negative-type photosensitive resin composition is preferably used for the usage of using a permanent film from the viewpoint of achieving a balance between the enhancement of the adhesiveness of the negative-type photosensitive resin composition after pre-baking to an Al pad and the prevention of the generation of residue of the negative-type photosensitive resin composition at the time of development, from the viewpoint of enhancing the adhesiveness of the cured film of the negative-type photosensitive resin composition after the heat treatment to metal, and from the viewpoint of improving the chemical resistance of the negative-type photosensitive resin composition after the heat treatment.

Furthermore, in the present embodiment, the resin film includes the cured film of the negative-type photosensitive resin composition. In other words, the resin film according to the present embodiment is obtained by curing the negative-type photosensitive resin composition.

The above-mentioned permanent film is composed of a resin film obtained by pre-baking, exposing, and developing the negative-type photosensitive resin composition to perform patterning into a desired shape, and thereafter curing by a heat treatment. The permanent film can be used as a protective film, an interlayer film, a dam material, and the like for a semiconductor device.

The above-mentioned resist is composed of a resin film obtained by applying the negative-type photosensitive resin composition by a method such as spin coating, roll coating, flow coating, dip coating, spray coating, and doctor coating to a target to be masked by the resist, and removing a solvent from the negative-type photosensitive resin composition.

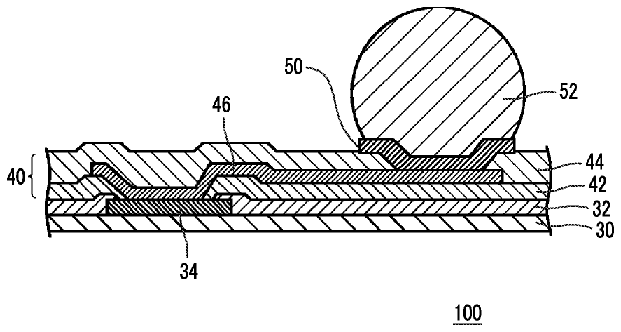

FIG. 1 shows an example of a semiconductor device according to the present embodiment.

A semiconductor device 100 according to the present embodiment can be a semiconductor device having the above-mentioned resin film. Specifically, in the semiconductor device 100, one or more of the group consisting of a passivation film 32, an insulating layer 42, and an insulating layer 44 can be formed from the resin film including the cured product of the present embodiment. The resin film is preferably the above-mentioned permanent film.

The semiconductor device 100 is a semiconductor chip, for example. In this case, a semiconductor package can be obtained by mounting the semiconductor device 100 on a wiring substrate through a bump 52, for example.

The semiconductor device 100 has a semiconductor substrate having a semiconductor element such as a transistor, and a multilayered wiring layer (not shown in the drawing) provided on the semiconductor substrate. The uppermost layer of the multilayered wiring layer having an insulating interlayer 30, and an uppermost layer wiring 34 provided on the insulating interlayer 30. The uppermost layer wiring 34 is composed of aluminum Al, for example. A passivation film 32 is provided on the insulating interlayer 30 and the uppermost layer wiring 34. A part of the passivation film 32 has an opening through which the uppermost layer wiring 34 is exposed.

A re-distribution layer 40 is provided on the passivation film 32. The re-distribution layer 40 has an insulating layer 42 provided on the passivation film 32, a re-distribution 46 provided on the insulating layer 42, and an insulating layer 44 provided on the insulating layer 42 and the re-distribution 46. An opening connected to the uppermost layer wiring 34 is formed in the insulating layer 42. The re-distribution 46 is formed on the insulating layer 42 and in the opening provided in the insulating layer 42, and is connected to the uppermost layer wiring 34. The insulating layer 44 has an opening connected to the re-distribution 46.

The bump 52 is formed in the opening provided in the insulating layer 44 through an Under Bump Metallurgy (UBM)) layer 50, for example. The semiconductor device 100 is connected to a wiring substrate or the like through the bump 52, for example.

Although the embodiments of the present invention have been described above, these are examples of the present invention, and various configurations other than the above-mentioned description can be adopted within a range not impairing the effects of the present invention.

### EXAMPLES

Hereinafter, the present invention will be described in more detail with reference to examples, but the present invention is not limited thereto.

The following compounds were used in the synthesis of polymers.

4,4-Diamino-3,3-diethyl-5,5-dimethyldiphenylmethane (hereinafter also referred to as MED-J) represented by the following formula.

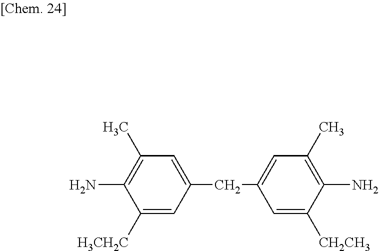

2,2-Bis(3-amino-4-hydroxyphenyl) propane (hereinafter also referred to as BAPA) represented by the following formula.

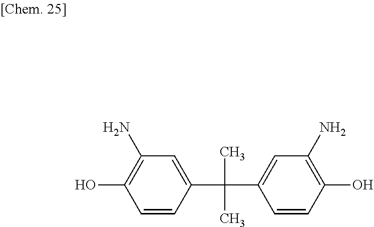 [SMILES: CC(C)(c1ccc(O)c(N)c1)c1ccc(O)c(N)c1]

2,2-Bis(3-amino-4-hydroxyphenyl) hexafluoropropane (hereinafter also referred to as BAFA) represented by the following formula.

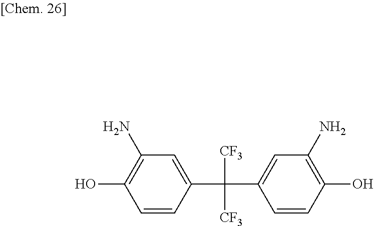 [SMILES: Nc1cc(C(c2ccc(O)c(N)c2)(C(F)(F)F)C(F)(F)F)ccc1O]

4,4′-Diamino-2,2′-bis(trifluoromethyl) biphenyl (hereinafter also referred to as TFMB) represented by the following formula.

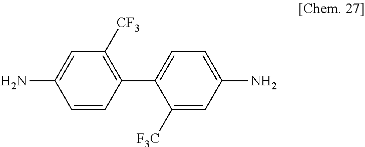 [SMILES: Nc1ccc(-c2ccc(N)cc2C(F)(F)F)c(C(F)(F)F)c1]

4,4′-(Hexafluoroisopropylidene)bis [(4-aminophenoxy)benzene](hereinafter also referred to as HFBAPP) represented by the following formula.

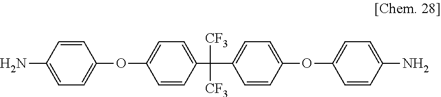 [SMILES: Nc1ccc(Oc2ccc(C(c3ccc(Oc4ccc(N)cc4)cc3)(C(F)(F)F)C(F)(F)F)cc2)cc1]

A mixture (hereinafter also referred to as TMDA) of 1-(4-aminophenyl)-1,3,3-trimethylphenylindan-6-amine and 1-(4-aminophenyl)-1,3,3-trimethylphenylindan-5-amine represented by the following formula.

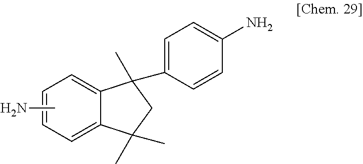

9,9-Bis(3-methyl-4-aminophenyl) fluorene (hereinafter also referred to as BTFL) represented by the following formula.

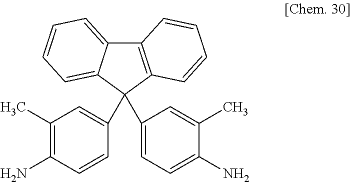 [SMILES: Cc1cc(C2(c3ccc(N)c(C)c3)c3ccccc3-c3ccccc32)ccc1N]

4-[4-(1,3-Dioxoisobenzofuran-5-ylcarbonyloxy)-2,3,5-trimethylphenyl]-2,3,6-trimethylphenyl 1,3-dioxoisobenzofuran-5-carboxylate (hereinafter also referred to as TMPBP-TME) represented by the following formula.

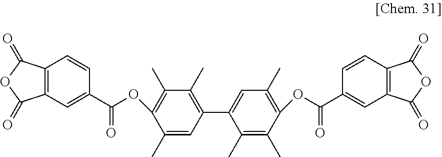 [SMILES: Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O]

p-Phenylene bis(trimellitate anhydride) (hereinafter also referred to as TMHQ) represented by the following formula.

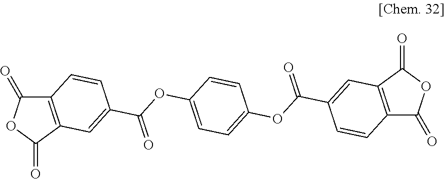 [SMILES: O=C(Oc1ccc(OC(=O)c2ccc3c(c2)C(=O)OC3=O)cc1)c1ccc2c(c1)C(=O)OC2=O]

### Example 1

First, 9.67 g (34.2 mmol) of MED-J, 2.95 g (11.4 mmol) of BAPA, and 33.62 g (54.3 mmol) of TMPBP-TME were put into a reaction container having an appropriate size and equipped with a stirrer and a cooling pipe. Thereafter, 138.71 g of GBL was added to the reaction container.

After ventilation with nitrogen for 10 minutes, the temperature was raised to 60° C. while stirring to cause a reaction for 1.5 hours. Thereafter, a reaction was further caused at 180° C. for 3 hours to polymerize a bisaminophenol and an acid anhydride, thereby producing a polymerization solution.

When GPC measurement of the polymer was performed, the weight-average molecular weight Mw was 21, 500, and the polydispersity (weight-average molecular weight Mw/number-average molecular weight Mn) was 2.02.

Subsequently, 6.44 g (45.6 mmol) of 2-isocyanatoethyl acrylate (hereinafter also referred to as AOI, manufactured by Showa Denko K. K.) and 43.02 g of γ-butyrolactone (GBL) were put to the total amount of the obtained polyimide solution (22.8 mmol in terms of hydroxyl group). Thereafter, the temperature was raised to 120° C. while stirring to cause a reaction for 6 hours.

The obtained reaction solution was diluted with tetrahydrofuran to produce a diluted solution. Subsequently, the diluted solution was added dropwise to methanol to precipitate a white solid. The obtained white solid was recovered and vacuum-dried at a temperature of 40° C. to obtain 43.73 g of a polymer.

When GPC measurement of the polymer was performed, the weight-average molecular weight Mw was 22, 800, and the polydispersity (weight-average molecular weight Mw/number-average molecular weight Mn) was 2.15.

In addition, when ¹H-NMR measurement was performed, a peak in the aromatic region (6.8 ppm to 8.8 ppm) was confirmed at an area ratio corresponding to the number of protons.

Furthermore, the introduction rate of the crosslinking group was 100% from the area ratio of the aromatic region (6.8 ppm to 8.8 ppm) and the alkene region (5.8 ppm to 6.3 ppm).

The polymer into which the crosslinking group was introduced partially had the repeating unit represented by the following formula.

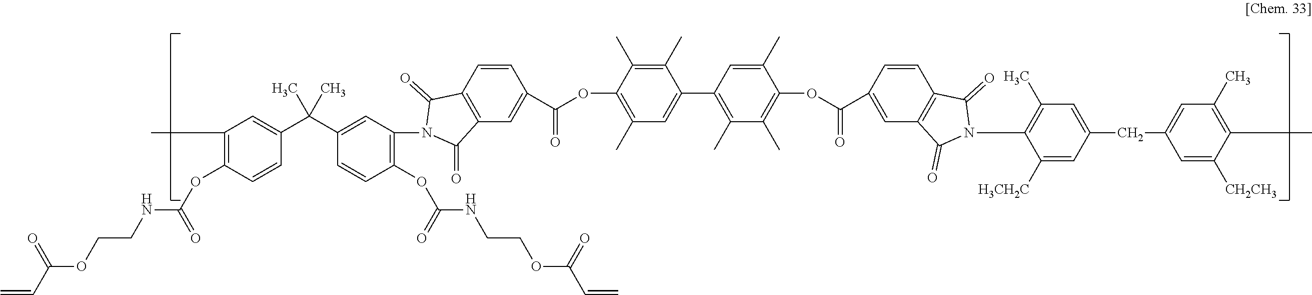

### Example 2

First, 12.89 g (45.7 mmol) of MED-J and 33.62 g (54.3 mmol) of TMPBP-TME were put into a reaction container having an appropriate size and equipped with a stirrer and a cooling pipe. Thereafter, 125.58 g of GBL was added to the reaction container.

After ventilation with nitrogen for 10 minutes, the temperature was raised to 60° C. while stirring to cause a reaction for 1.5 hours. Thereafter, a reaction was further caused at 180° C. for 3 hours to polymerize a bisaminophenol and an acid anhydride, thereby producing a polymerization solution.

When GPC measurement of the polymer was performed, the weight-average molecular weight Mw was 23, 600, and the polydispersity (weight-average molecular weight Mw/number-average molecular weight Mn) was 2.05.

Subsequently, 4.91 g (34.8 mmol) of 2-isocyanatoethyl acrylate (hereinafter also referred to as AOI, manufactured by Showa Denko K. K.) and 44.06 g of γ-butyrolactone (GBL) were put to the total amount of the obtained polyimide solution (17.4 mmol in terms of no terminal acid). Thereafter, the temperature was raised to 120° C. while stirring to cause a reaction for 6 hours.

The obtained reaction solution was diluted with tetrahydrofuran to produce a diluted solution. Subsequently, the diluted solution was added dropwise to methanol to precipitate a white solid. The obtained white solid was recovered and vacuum-dried at a temperature of 40° C. to obtain 41.73 g of a polymer.

When GPC measurement of the polymer was performed, the weight-average molecular weight Mw was 23, 100, and the polydispersity (weight-average molecular weight Mw/number-average molecular weight Mn) was 2.09.

In addition, when 1H-NMR measurement was performed, a peak in the aromatic region (6.9 ppm to 8.9 ppm) was confirmed at an area ratio corresponding to the number of protons.

Furthermore, the introduction rate of the crosslinking group to the terminal was 100% as calculated from the area ratio of the aromatic region (6.9 ppm to 8.9 ppm) and the alkene region (5.8 ppm to 6.5 ppm) and the degree of polymerization.

The obtained polymer partially had the repeating unit represented by the following formula, and the crosslinking group was introduced into the terminal.

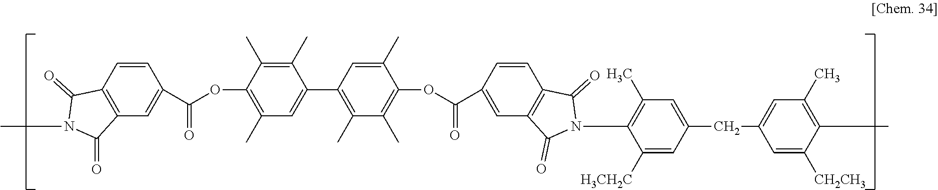

### Examples 3 to 6 and Comparative Examples 1 to 5

For Examples 3 to 6 and Comparative Examples 1 to 5, synthesis was performed in the same technique as in Example 1 except under the conditions shown in Table 1. Table 1 shows the obtained Mw, the obtained Mw/Mn, and the obtained crosslinking group introduction rate.

In Comparative Examples 1 and 2, gelation occurred during the polymerization reaction, which made it difficult for the reaction to proceed, and thus the solvent solubility in GBL was evaluated as “x”.

### [Average Value of Positive Electric Charges (δ+) of Two Carbonyl Carbons of Imide Ring]

The average value of the positive electric charges (δ+) of two carbonyl carbons of the imide ring of the negative-type photosensitive polymer obtained in Example 1 was calculated as follows.

The negative-type photosensitive polymer of Example 1 had a structural unit (A) of Chemical Formula (A) below and a structural unit (B) of Chemical Formula (B) below.

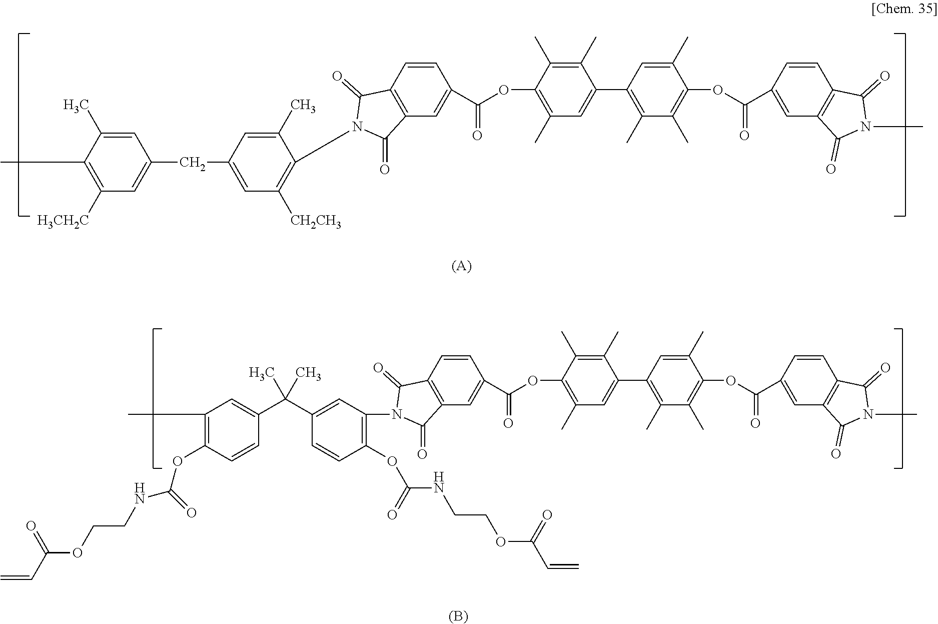

In this case, a compound (A′) represented by Chemical Formula (A′) below was measured by a charge equilibration method using soft HSPiP (ver. 5.3), and δ+ of two carbonyl carbons (*1, *2) of the imide ring contained in the above-mentioned compound (A′) was averaged to obtain an average value (1). A compound (B′) represented by Chemical Formula (B′) below was measured in the same manner, and δ+ of two carbonyl carbons (*1, *2) of the imide ring contained in the above-mentioned compound was averaged to obtain an average value (2). In addition, when the total of the number of moles (34.2 mmol) of the structural unit (A) and the number of moles (11.4 mmol) of the structural unit (B) was set to 100, δ+ was calculated by the following formula.

$$[ average value ( 1 ) of δ + \times molar fraction ( 1 ) + average value ( 2 ) of δ + \times molar fraction ( 2 ) ] \text{} / 100 = [ 0.087 \times 75 + 0.098 \times 25 ] / 100 = 0.09 \qquad Formula$$

The calculation was performed in the same manner for the other examples and comparative examples.

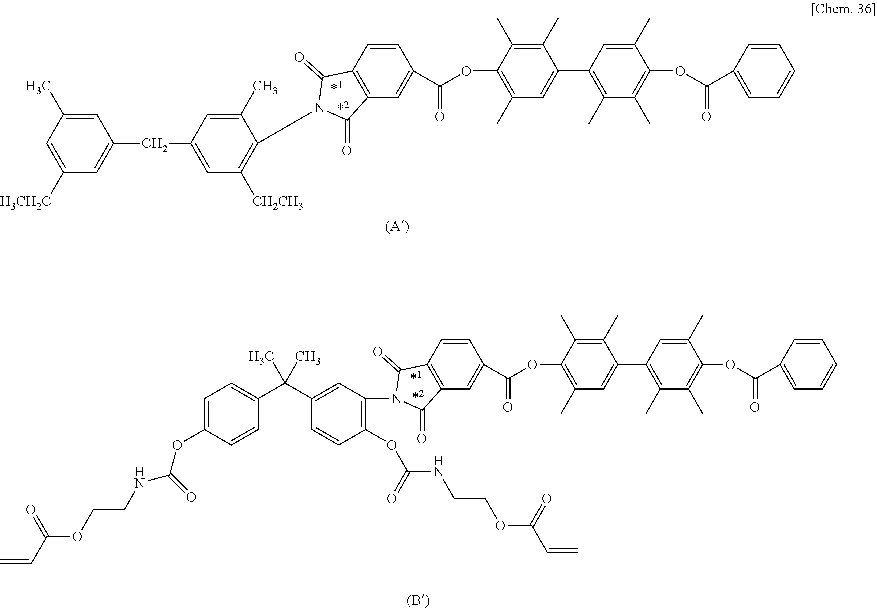

### [Solubility in Organic Solvent]

The solubility of the negative-type photosensitive polymers obtained in the examples and the comparative examples in γ-butyrolactone (GBL) or OK73 (a mixed solution of propylene glycol monomethyl ether (PGME) and propylene glycol monomethyl ether acetate (PGMEA) (mixing ratio 7:3), manufactured by TOKYO OHKA KOGYO CO., LTD.) was evaluated using the following criteria. Table 1 shows the results.

### (Evaluation Criteria of Solubility)

o: equal to or more than 5% by mass of the polymer was dissolved.
Δ: 1% to 5% by mass of the polymer was dissolved.
x: the solubility of the polymer was less than 1% by mass.

### [Hydrolysis Resistance]

The reduction rates of the weight-average molecular weights of the negative-type photosensitive polymers obtained in the examples and the comparative examples were measured under the following condition. Table 1 shows the results.

### (Condition (No Addition of Triethylamine))

When 400 parts by mass of γ-butyrolactone, 200 parts by mass of 4-methyltetrahydropyran, and 50 parts by mass of water were added to 100 parts by mass of the negative-type photosensitive polymer to stir at 100° C. for 6 hours, calculation was carried out by the following expression.

Expression: [(weight-average molecular weight before test−weight-average molecular weight after test)/weight-average molecular weight before test]×100

### (Condition (Addition of Triethylamine))

When 10 parts by mass of triethylamine, 400 parts by mass of γ-butyrolactone, 200 parts by mass of 4-methyltetrahydropyran, and 50 parts by mass of water were added to 100 parts by mass of the negative-type photosensitive polymer to stir at 100° C. for 6 hours, calculation was carried out by the following expression.

Expression: [(weight-average molecular weight before test−weight-average molecular weight after test)/weight-average molecular weight before test]×100

### [Elongation Percentage]

A silicon wafer surface was spin-coated with a composition containing the polymer solution (100 parts by mass of the polymer) obtained in the comparative example, 5 parts by mass of a thermal radical generator Perkadox BC, 2 parts by mass of an adhesion aid KBM-503P, and 0.1 part by mass of a surfactant FC4432. After pre-baking at 110° C. for 3 minutes, a film was prepared by heat treatment at 170° C. for 240 minutes under nitrogen. The details of each of the components were described below.

A tensile test (stretching speed: 5 mm/minute) was performed in an atmosphere of 23° C. on a test piece (6.5 mm×60 mm×10 μm thick) cut out from the obtained film. The tensile test was performed using a tension tester (TENSILON RTC-1210A) manufactured by ORIENTEC CO., LTD. Ten test pieces were measured to calculate the tensile elongation percentage from a fracture distance and an initial distance, and the maximum value of the elongation percentage was obtained.

Furthermore, HAST (unsaturated pressurized steam test) was performed on the above-mentioned test pieces cut out from the above-mentioned films for 96 hours under the condition at a temperature of 130° C. and a relative humidity of 85% RH. Thereafter, the maximum value of the elongation percentage was obtained in the same manner as described above.

TABLE 1

| | | Example 1 | Example 2 | Example 3 | Example 4 | Example 5 | Example 6 |
|---|---|---|---|---|---|---|---|
| Diamine 1 | Type | MED-J | MED-J | MED-J | MED-J | TMDA | BTFL |
| | Charging molar ratio | 63 | 84 | 67 | 42 | 42 | 42 |
| Bis(aminophenol) | Type | BAPA | | BAPA | BAPA | BAPA | BAPA |
| | Charging molar ratio | 21 | | 23 | 42 | 42 | 42 |
| Acid anhydride | Type | TMPBP-TME | TMPBP-TME | TMPBP-TME | TMHQ | TMPBP-TME | TMPBP-TME |
| | Charging molar ratio | 100 | 100 | 100 | 100 | 100 | 100 |
| Mw | | 22,800 | 23,100 | 46,900 | 22,200 | 17,200 | 18,600 |
| PDI | | 2.15 | 2.09 | 2.96 | 2.29 | 1.78 | 1.83 |
| AOI introduction rate | | 100% | — | 94% | 97% | 100% | — |
| Average value of δ+ | | 0.090 | 0.087 | 0.090 | 0.098 | 0.095 | 0.095 |
| Solvent solubility | GBL | ∘ | ∘ | ∘ | ∘ | ∘ | ∘ |
| | OK73 | ∘ | ∘ | ∘ | x | Δ | ∘ |
| Hydrolysis resistance | TEA not added | 2% | 0% | 3% | 8% | 3% | 4% |
| (Mw reduction rate) | TEA added | 21% | 7% | 38% | 81% | 37% | 32% |
| Elongation | Before HAST | — | — | — | — | — | — |
| | After HAST | — | — | — | — | — | — |

| | | | Comparative | Comparative | Comparative | Comparative |
|---|---|---|---|---|---|---|
| | | Comparative Example 1 | Example 2 | Example 3 | Example 4 | Example 5 |
| Diamine 1 | Type | Tetramethylbenzidine | m-Tolidine | MED-J | TFMB | HFBAPP |
| | Charging molar ratio | 42 | 42 | 42 | 42 | 42 |
| Bis(aminophenol) | Type | BAFA | BAFA | BAFA | BAFA | BAFA |
| | Charging molar ratio | 42 | 42 | 42 | 42 | 42 |
| Acid anhydride | Type | TMPBP-TME | TMPBP-TME | TMPBP-TME | TMPBP-TME | TMPBP-TME |
| | Charging molar ratio | 100 | 100 | 100 | 100 | 100 |
| Mw | | — | — | 20,800 | 32,600 | 21,800 |
| PDI | | — | — | 1.85 | 2.35 | 1.80 |
| AOI introduction rate | | — | — | 77% | 100% | 84% |
| Average value of δ+ | | — | — | 0.100 | 0.111 | 0.108 |
| Solvent solubility | GBL | — | — | ∘ | ∘ | ∘ |
| | OK73 | — | — | ∘ | ∘ | ∘ |
| Hydrolysis resistance | TEA not added | — | — | 12% | 27% | 16% |
| (Mw reduction rate) | TEA added | — | — | 33% | 73% | 50% |
| Elongation | Before HAST | — | — | 29% | 23% | 30% |
| | After HAST | — | — | 11% | 7% | 14% |

As shown in Table 1, in the negative-type photosensitive polymer of the present invention obtained in the examples in which the average value of the positive electric charges (5+) of two carbonyl carbons of the imide ring was equal to or less than 0.099, it was observed that the solubility in an organic solvent was excellent, and that because hydrolysis was inhibited, a decrease in the elongation percentage was small, and a reduction in mechanical strength was minimized.

The following compounds were used in the preparation of the negative-type photosensitive resin composition.

### (Crosslinking Agent)

Acrylic compound 1: dipentaerythritol hexaacrylate (manufactured by Shin-Nakamura Chemical Co., Ltd., NK Ester A-DPH)

### (Polymerization Initiator)

Photoradical generator: 2-(dimethylamino)-1-(4-(4-morpholino)phenyl)-2-(phenylmethyl)-1-butanone (Irgacure Oxe01, manufactured by BASF Japan Ltd.)
Thermal radical generator: dicumyl peroxide (Perkadox BC, peroxide, manufactured by Kayaku Akzo Corporation)

### (Adhesion Aid)

Adhesion aid 1: 3-methacryloxypropyltrimethoxysilane (KBM-503P, manufactured by Shin-Etsu Chemical Co., Ltd.)

### (Surfactant)

Surfactant 1: surfactant having a fluorocarbon chain (FC-4432, manufactured by Sumitomo 3M Ltd.)

### (Solvent)

Solvent 1: γ-butyrolactone (GBL)

### Example 7

### (Preparation of Negative-Type Photosensitive Resin Composition)

The polymer (100 parts by mass of the polymer) of Example 3 and a resultant product obtained by preliminarily dissolving the component shown in Table 2 to obtain a 22 wt % GBL solution were mixed to prepare a photosensitive resin composition.

A silicon wafer surface was spin-coated with the obtained negative-type photosensitive resin composition such that the film thickness after drying was 10 μm to perform pre-baking at 120° C. for 3 minutes. Thereafter, exposure to 600 mJ/cm² was performed using a high-pressure mercury lamp. Thereafter, a heat treatment was performed at 170° C. for 120 minutes in a nitrogen atmosphere to prepare a film.

For the obtained film, the glass transition temperature (Tg) and the elongation were measured by the following method to evaluate the patterning characteristics. Table 2 shows the results.

### [Glass Transition Temperature (Tg)]

A test piece of 8 mm×40 mm was cut out from the film obtained in Example 7. Dynamic mechanical analysis was performed on this test piece at a temperature rising rate of 5° C./minute and a frequency of 1 Hz using dynamic mechanical analysis (DMA device, manufactured by TA Instruments, Q800). A temperature at which a loss tangent tan δ was a maximum value was measured as a glass transition temperature.

### [Elongation Percentage]

A tensile test (stretching speed: 5 mm/minute) was performed in an atmosphere of 23° C. on test pieces (6.5 mm×60 mm×10 μm thick) cut out from the film obtained in Example 7. The tensile test was performed using a tension tester (TENSILON RTC-1210A) manufactured by ORIENTEC CO., LTD. Five test pieces were measured, and the stresses at the fracturing point were averaged to obtain a strength. The tensile elongation percentage was calculated from a fracture distance and an initial distance, and the average value and the maximum value of the elongation percentage were obtained.

Furthermore, HAST (unsaturated pressurized steam test) was performed on the above-mentioned test pieces cut out from the film obtained in Example 7 for 96 hours under the condition at a temperature of 130° C. and a relative humidity of 85% RH. Thereafter, the average value and the maximum value of the elongation percentage were obtained in the same manner as described above.

### [Evaluation Relating to Patterning Characteristics]

Whether the photosensitive resin composition of Example 7 could be sufficiently patterned by exposure and development was confirmed as follows.

The photosensitive resin composition of Example 7 was applied onto an 8-inch silicon wafer using a spin coater. After the application, pre-baking was performed for 3 minutes at 110° C. on a hot plate in the atmosphere to obtain a coating film having a film thickness of about 5.0 μm.

This coating film was irradiated with i-line through a mask in which a via pattern having a width of 20 μm was drawn. For irradiation, an i-line Stepper (manufactured by Nikon Corporation, NSR-4425i) was used.

After exposure, spray development was performed for 40 seconds using cyclopentanone as a developing solution, and spray development was further performed for 10 seconds using PGMEA as a developing solution to dissolve and remove unexposed portions, and thereby a via pattern was obtained.

The cross-section of the obtained via pattern was observed using a tabletop-SEM. The width at an intermediate height of the bottom surface of the via pattern and the opening was defined as a via width, which was evaluated according to the following criteria.

Favorable patterning properties: a via pattern of 20 μm was opened.

Poor patterning properties: a via pattern of 20 μm was not opened.

The coating film obtained from the photosensitive resin composition of Example 7 had favorable patterning properties.

TABLE 2

| | | | Example 7 |
|---|---|---|---|
| Polyimide | Polyimide of Example 3 | Part by | 100 |
| Crosslinking agent | Acrylic compound 1 | mass | 9 |
| Polymerization | Photoradical generator | | 10 |
| initiator | Thermal radical generator | | 5 |
| Adhesion aid | Adhesion aid 1 | | 2 |
| Surfactant | Surfactant 1 | | 0.05 |
| Solvent | Solvent 1 | | 446 |
| Tg | | ° C. | 273 |
| Elongation (MAX) | Before uHAST | % | 47 |
| Elongation (MAX) | After uHAST | % | 46 |
| Elongation (Ave.) | Before uHAST | % | 37 |
| Elongation (Ave.) | After uHAST | % | 35 |

| | |
|---|---|
| Patterning characteristics | Favorable |

As shown in Table 2, in the film obtained from the negative-type photosensitive resin composition containing the negative-type photosensitive polymer in which the average value of the positive electric charges (δ+) of two carbonyl carbons of the imide ring was equal to or less than 0.099, it was clarified that elongation was excellent, and it was also clarified that mechanical strength was excellent even after the HAST test since the negative-type photosensitive polymer having excellent hydrolysis resistance was contained. In addition, it was confirmed that the patterning properties were also favorable, and suitable use as a negative-type photosensitive resin composition was possible.

The present application claims priority based on Japanese Patent Application No. 2021-105682 filed on Jun. 25, 2021 and Japanese Patent Application No. 2022-019323 filed on Feb. 10, 2022, the disclosure of which is incorporated herein in its entirety.

### REFERENCE SIGNS LIST

100 semiconductor device
30 insulating interlayer
32 passivation film
34 uppermost layer wiring
40 re-distribution layer
42 insulating layer
44 insulating layer
46 re-distribution
50 UBM layer
52 bump

1. A solvent-soluble negative-type photosensitive polymer which has a structural unit containing an imide ring, the negative-type photosensitive polymer comprising
a group having a terminal double bond,
wherein an average value of positive electric charges (δ+) of two carbonyl carbons of the imide ring is equal to or less than 0.099 as calculated by a charge equilibration method.

2. The negative-type photosensitive polymer according to claim 1,
wherein a fluorine atom is not contained in a molecular structure.

3. The negative-type photosensitive polymer according to claim 1,
wherein the structural unit is represented by General Formula (1), 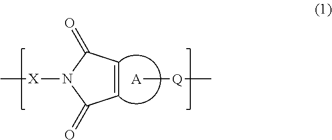
wherein in General Formula (1), X represents a divalent organic group including an aromatic group; A represents a ring structure having two carbons of the imide ring; and Q represents a divalent organic group.

4. The negative-type photosensitive polymer according to claim 3, further comprising
an electron-donating group at two ortho positions with respect to a carbon atom bonded to a nitrogen atom in General Formula (1),
wherein the aromatic group included in the divalent organic group as X in General Formula (1) is bonded to the nitrogen atom.

5. The negative-type photosensitive polymer according to claim 3,
wherein X in General Formula (1) is a divalent group represented by General Formula (1a) or General Formula (1b), 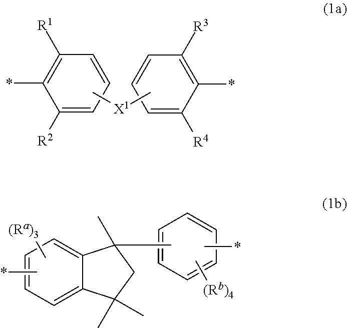
wherein in General Formula (1a), R¹ to R⁴ each independently represent a hydrogen atom, an alkyl group having 1 to 3 carbon atoms, or an alkoxy group having 1 to 3 carbon atoms, provided that R¹ and R² are different groups, and R³ and R⁴ are different groups; X¹ represents a single bond, —SO₂—, —C(═O)—, a linear or branched alkylene group having 1 to 5 carbon atoms, or a fluorenylene group; and * represents a bonding site, and
wherein in General Formula (1b), R^{a} and R^{b} each independently represent a hydrogen atom, an alkyl group having 1 to 3 carbon atoms, or an alkoxy group having 1 to 3 carbon atoms, provided that a plurality of R^{a}'s may be the same as or different from each other, and a plurality of R^{b}'s may be the same as or different from each other; and * represents a bonding site.

6. The negative-type photosensitive polymer according to claim 3,
wherein X in General Formula (1) includes a divalent group represented by General Formula (1c) having a group having a terminal double bond, 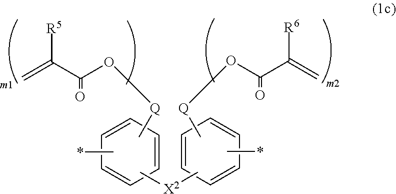
wherein in General Formula (1c), Q's each represent divalent to tetravalent organic groups having 1 to 10 carbon atoms, provided that a plurality of Q's may be the same as or different from each other; R⁵ and R⁶ each independently represent a hydrogen atom, an alkyl group having 1 to 3 carbon atoms, or an alkoxy group having 1 to 3 carbon atoms; m1 and m2 each independently represent an integer of 1 to 3; X² represents a single bond, —SO₂—, —C(═O)—, or a linear or branched alkylene group having 1 to 5 carbon atoms; and * represents a bonding site.

7. The negative-type photosensitive polymer according to claim 1,
wherein the negative-type photosensitive polymer comprises the group having a terminal double bond at at least one of both terminals.

8. The negative-type photosensitive polymer according to claim 3,
wherein A in General Formula (1) is an aromatic ring.

9. The negative-type photosensitive polymer according to claim 3,
wherein Q in General Formula (1) is a divalent group containing an imide ring.

10. The negative-type photosensitive polymer according to claim 5,
wherein the structural unit represented by General Formula (1) includes a structural unit represented by General Formula (1-1), 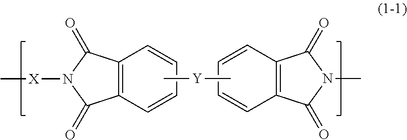
wherein in General Formula (1-1), X is the divalent group represented by General Formula (1a) or General Formula (1b); and Y is a divalent organic group.

11. The negative-type photosensitive polymer according to claim 10,
wherein X in General Formula (1-1) includes a divalent group represented by General Formula (1c).

12. The negative-type photosensitive polymer according to claim 10,
wherein Y in General Formula (1-1) is a divalent organic group selected from General Formula (a1-1), General Formula (a1-2), General Formula (a1-3), and General Formula (a1-4), 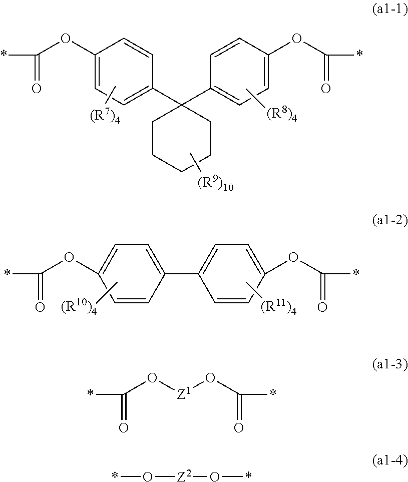
wherein in General Formula (a1-1), R⁷ and R⁸ each independently represent a hydrogen atom, an alkyl group having 1 to 3 carbon atoms, or an alkoxy group having 1 to 3 carbon atoms, provided that a plurality of R⁷'s may be the same as or different from each other, and a plurality of R⁸'s may be the same as or different from each other; R⁹ represents a hydrogen atom, an alkyl group having 1 to 3 carbon atoms, or an alkoxy group having 1 to 3 carbon atoms, provided that a plurality of R⁹'s may be the same as or different from each other; and * represents a bonding site,
wherein in General Formula (a1-2), R¹⁰ and R¹¹ each independently represent a hydrogen atom, an alkyl group having 1 to 3 carbon atoms, or an alkoxy group having 1 to 3 carbon atoms, provided that a plurality of R¹⁰'s may be the same as or different from each other, and a plurality of R¹¹'s may be the same as or different from each other; and * represents a bonding site,
wherein in General Formula (a1-3), Z¹ represents an alkylene group having 1 to 5 carbon atoms or a divalent aromatic group; and * represents a bonding site, and
wherein in General Formula (a1-4), Z² represents a divalent aromatic group; and represents a bonding site.

13. The negative-type photosensitive polymer according to claim 1,
wherein equal to or more than 5% by mass of the negative-type photosensitive polymer is dissolved in a solvent selected from N-methyl-2-pyrrolidone, N-ethyl-2-pyrrolidone, γ-butyrolactone (GBL), and cyclopentanone.

14. The negative-type photosensitive polymer according to claim 1,
wherein equal to or more than 5% by mass of the negative-type photosensitive polymer is dissolved in γ-butyrolactone (GBL).

15. The negative-type photosensitive polymer according to claim 1,
wherein a reduction rate of a weight-average molecular weight measured under the following condition is equal to or less than 15%,
(condition)
when 400 parts by mass of γ-butyrolactone, 200 parts by mass of 4-methyltetrahydropyran, and 50 parts by mass of water are added to 100 parts by mass of the negative-type photosensitive polymer to stir at 100° C. for 6 hours, calculation is carried out by the following expression,
expression: [(weight-average molecular weight before test−weight-average molecular weight after test)/weight-average molecular weight before test]×100.

16. A polymer solution comprising
the negative-type photosensitive polymer according to claim 1.

17. A negative-type photosensitive resin composition comprising:
(A) the negative-type photosensitive polymer according to claim 1;
(B) a crosslinking agent including a polyfunctional (meth)acrylate; and
(C) a photopolymerization initiator.

18. A cured film comprising
a cured product of the negative-type photosensitive resin composition according to claim 17.

19. A semiconductor device comprising
a resin film including a cured product of the negative-type photosensitive resin composition according to claim 17.
